(19) United States
(12) Patent Application Publication
(10) Pub. No.: US 2025/0280694 A1
(43) Pub. Date: Sep. 4, 2025

(54) DISPLAY DEVICE AND METHOD OF MANUFACTURING DISPLAY DEVICE

(71) Applicant: Samsung Display Co., LTD., Yongin-si (KR)

(72) Inventors: Tae Young SONG, Yongin-si (KR); Young Soo KWON, Yongin-si (KR); Won Gap YOON, Yongin-si (KR); Ki Heon LEE, Yongin-si (KR)

(73) Assignee: Samsung Display Co., LTD., Yongin-si (KR)

(21) Appl. No.: 18/936,032

(22) Filed: Nov. 4, 2024

(30) Foreign Application Priority Data
Feb. 29, 2024 (KR) 10-2024-0029720

(51) Int. Cl. H10K 59/38; H10K 59/12; H10K 59/122

(52) U.S. Cl. CPC H10K 59/38; H10K 59/1201; H10K 59/122

(57) ABSTRACT

An embodiment provides a display device and a method of manufacturing the display device. The display device includes a display layer, and a light controlling layer that is disposed on the display layer and includes a bank, a middle bank part directly adjacent to the bank, and a color conversion layer. The light controlling layer includes an opening in which the bank and the middle bank part are not disposed. The color conversion layer may include a base color conversion layer disposed in at least a portion of the opening and a protruding color conversion layer overlapping the middle bank part in a plan view.

### CROSS-REFERENCE TO RELATED APPLICATION(S)

This application claims priority to and benefits of Korean Patent Application No. 10-2024-0029720, filed on Feb. 29, 2024, in the Korean Intellectual Property Office, the entire contents of which are incorporated herein by reference.

### BACKGROUND

### 1. Technical Field

Embodiments relate to a display device and a method of manufacturing the display device.

### 2. Description of the Related Art

Recently, as interest in an information display is increasing, research and development for display devices are continuously conducted.

### SUMMARY

Embodiments provide a display device capable of improving process convenience and a method of manufacturing the display device.

Embodiments provide a display device capable of reducing process costs, and a method of manufacturing the display device.

Embodiments provide a display device with high resolution and improved display quality and a method of manufacturing the display device.

An embodiment provides a display device including: a display layer, and a light controlling layer that is disposed on the display layer and includes a bank, a middle bank part directly adjacent to the bank, and a color conversion layer. The light controlling layer may include an opening in which the bank and the middle bank part are not disposed. The color conversion layer may include a base color conversion layer disposed in at least a portion of the opening and a protruding color conversion layer overlapping the middle bank part in a plan view.

The bank may have a height greater than the middle bank part.

The base color conversion layer and the protruding color conversion layer may be integral with each other and may include a same material. The bank and the middle bank part may be integral with each other and include a same material. The base color conversion layer may have a larger volume than the protruding color conversion layer.

The display device may include a sub-pixel area in which light of a color is provided and a non-sub-pixel area adjacent to the sub-pixel area. The sub-pixel area may include a first sub-pixel area in which light of a first color is provided, a second sub-pixel area in which light of a second color is provided, and a third sub-pixel area in which light of a third color is provided. The opening may include, in a plan view, a first opening overlapping the first sub-pixel area, a second opening overlapping the second sub-pixel area, and a third opening overlapping the third sub-pixel area. The protruding color conversion layer may overlap the non-sub-pixel area in a plan view.

The first opening and the second opening may be spaced apart from each other by a first distance. The second opening and the third opening may be spaced apart from each other by a second distance smaller than the first distance.

The protruding color conversion layer may include a first protruding color conversion layer adjacent to the first sub-pixel area and a second protruding color conversion layer adjacent to the second sub-pixel area. The first sub-pixel area, the second sub-pixel area, and the third sub-pixel area may be adjacent to each other in a first direction. The first protruding color conversion layer and the second protruding color conversion layer may overlap in a second direction different from the first direction.

The middle bank part may include an upper surface forming a lower height than the bank and an inclined surface facing the base color conversion layer.

The middle bank part may include an inclined surface having an end portion adjacent to the bank and another end portion adjacent to an upper surface of the display layer.

The middle bank part may include an inclined surface whose end portion is adjacent to the bank and a side surface facing the base color conversion layer.

The middle bank part may include a first middle bank part disposed on a side of the base color conversion layer and a second middle bank part disposed on another side of the base color conversion layer.

The display device may include a first sub-pixel providing a first color, a second sub-pixel providing a second color, and a third sub-pixel providing a third color; and a scattering layer included in the third sub-pixel. The color conversion layer may include a first color conversion layer forming the first sub-pixel and a second color conversion layer forming the second sub-pixel. The base color conversion layer may include a first base color conversion layer included in the first color conversion layer and a second base color conversion layer included in the second color conversion layer. The protruding color conversion layer may include a first protruding color conversion layer included in the first color conversion layer and a second protruding color conversion layer included in the second color conversion layer.

The display device may include a first sub-pixel providing a first color, a second sub-pixel providing a second color, and a third sub-pixel providing a third color; and a scattering layer included in the third sub-pixel. The protruding color conversion layer may be formed in the second sub-pixel, without being formed in the first sub-pixel.

The first sub-pixel may be disposed between the second sub-pixel and the third sub-

pixel. The protruding color conversion layer may include a plurality of protruding color conversion layers. Some of the plurality of protruding color conversion layers may be disposed on a side of the base color conversion layer, and others of the plurality of protruding color conversion layers may be disposed on another side of the base color conversion layer.

The display device may include pixels respectively including a plurality of sub-pixels forming a plurality of sub-pixel areas. The plurality of sub-pixel areas may be spaced apart from each other in a first direction. The pixels may include a first pixel and a second pixel that are spaced apart from each other in a second direction different from the first direction. The middle bank part may be disposed between the opening of the first pixel and the opening of the second pixel.

The display device may include a fluid passage that is formed between the opening of the first pixel and the opening of the second pixel and in which the middle bank part is not disposed.

The display device may further include a color filter layer disposed on the light controlling layer and including a color filter. The display layer may include a light emitting element that provides light to a light emitting area. The light emitting area may overlap the color filter and the color conversion layer in a plan view.

The display device may include a sub-pixel area in which light of a color is provided and a non-sub-pixel area adjacent to the sub-pixel area. The sub-pixel area may include a first sub-pixel area in which light of a first color is provided, a second sub-pixel area in which light of a second color is provided, and a third sub-pixel area in which light of a third color is provided. The light emitting element may emit light including a light component of the third color.

Another embodiment provides a method of manufacturing a display device, including: manufacturing a display layer; and forming a light controlling layer on the display layer. The forming of the light controlling layer may include patterning a bank and a middle bank part on the display layer; and patterning a color conversion layer and a scattering layer on the display layer. The patterning of the bank and the middle bank part may include forming an opening in which the bank and the middle bank part are not disposed. The color conversion layer may include a base color conversion layer and a protruding color conversion layer. The patterning of the color conversion layer may include disposing the base color conversion layer in the opening and disposing the protruding color conversion layer to overlap the middle bank part in a plan view.

The patterning of the bank and the middle bank part may include forming an inkjet margin area that overlaps the middle bank part in a plan view. The patterning of the color conversion layer may include providing ink to an ink provision area formed across the opening and the inkjet margin area.

The patterning of the color conversion layer may include moving the ink provided in the ink provision area to an area within the opening.

The protruding color conversion layer may include a plurality of protruding color conversion layers. Some of the plurality of protruding color conversion layers may be disposed on a side of the base color conversion layer, and others of the plurality of protruding color conversion layers may be disposed on another side of the base color conversion layer.

The opening may include openings respectively included in different pixels. The inkjet margin area may be disposed between the openings.

The ink provision area may have an ink area length, and the opening may have an opening width. The ink area length may be larger than the opening width.

The patterning of the bank and the middle bank part may include forming the bank and the middle bank part using a mask or slit-type mask including a halftone area.

According to the embodiment of the disclosure, a display device with improved process convenience may be provided.

According to the embodiment, a display device and a method of manufacturing the display device capable of reducing process costs may be provided.

According to the embodiment, a display device with high resolution and improved display quality and a method of manufacturing the display device may be provided.

### BRIEF DESCRIPTION OF THE DRAWINGS

FIG. 1 illustrates a schematic top plan view of a display device according to an embodiment.

FIG. 2 illustrates a schematic cross-sectional view of a display device according to an embodiment.

FIG. 3 illustrates a schematic view of a display layer according to an embodiment.

FIGS. 4, 5, and 6 illustrate schematic top plan views of a display device according to an embodiment.

FIG. 7 illustrates a schematic cross-sectional view taken along line A-A′ of FIG. 4 to FIG. 6.

FIGS. 8, 10, 11, 12, and 13 illustrate schematic cross-sectional views of a structure formed by a bank and a middle bank part according to an embodiment.

FIG. 9 illustrates a schematic top plan view of a step of performing an inkjet printing process among steps of a method of manufacturing a display device according to an embodiment.

FIGS. 14, 15, and 16 illustrate schematic top plan views of a display device according to another embodiment.

FIG. 17 illustrates a schematic cross-sectional view taken along line B-B′ of FIG. 14 to FIG. 16.

FIGS. 18, 19, and 20 illustrate schematic top plan views of a display device according to another embodiment.

FIG. 21 and FIG. 23 illustrate schematic cross-sectional views taken along line C-C′ of FIG. 18 to FIG. 20.

FIG. 22 and FIG. 24 illustrate schematic cross-sectional views taken along line D-D′ of FIG. 18 to FIG. 20.

FIG. 25 illustrates a flowchart showing a method of manufacturing a display device according to an embodiment.

FIG. 26 illustrates a flowchart showing steps of forming a light controlling layer on a display layer of FIG. 25.

FIGS. 27, 28, 29, 30, 31, and 32 illustrate schematic views of process steps of a method of manufacturing a display device according to an embodiment.

FIG. 33 illustrates a schematic top plan view of a step of performing an inkjet printing process among process steps of a method of manufacturing a display device according to another embodiment.

FIG. 34 illustrates a schematic top plan view of a step of performing an inkjet printing process among process steps of a method of manufacturing a display device according to another embodiment.

### DETAILED DESCRIPTION OF THE EMBODIMENTS

Since the disclosure may be variously modified and have various forms, embodiments will be illustrated and described in detail in the following. This, however, by no means restricts the invention to the embodiments, and it is to be understood as embracing all included in the spirit and scope of the disclosure changes, equivalents, and substitutes.

Terms such as first, second, and the like will be used only to describe various constituent elements, and are not to be interpreted as limiting these constituent elements. These terms are only used to differentiate one constituent element from another. For example, a first constituent element may be referred to as a second constituent element, and similarly, a second constituent element may be referred to as a first constituent element, without departing from the scope of the disclosure. Singular forms are intended to include plural forms unless the context clearly indicates otherwise.

In the disclosure, it should be understood that the term “include”, “comprise”, “have”, or “configure” indicates that a feature, a number, a step, an operation, a constituent element, a part, or a combination thereof described in the description is present, but does not exclude a possibility of presence or addition of one or more other features, numbers, steps, operations, constituent elements, parts, or combinations, in advance. It will be understood that when an element such as a layer, film, region, area, or substrate is referred to as being “on” another element, it can be directly on the other element or intervening elements may also be present. In the description, when a portion of a layer, film, region, area, plate, or the like is referred to as being formed “on” another portion, the formed direction is not limited to an upper direction but includes a lateral or lower direction. In contrast, when an element of a layer, film, region, area, plate, or the like is referred to as being “below” another element, it may be directly below the other element, or intervening elements may be present.

The disclosure relates to a display device and a method of manufacturing the display device. Hereinafter, a display device and a method of manufacturing the display device according to an embodiment will be described with reference to the accompanying drawings.

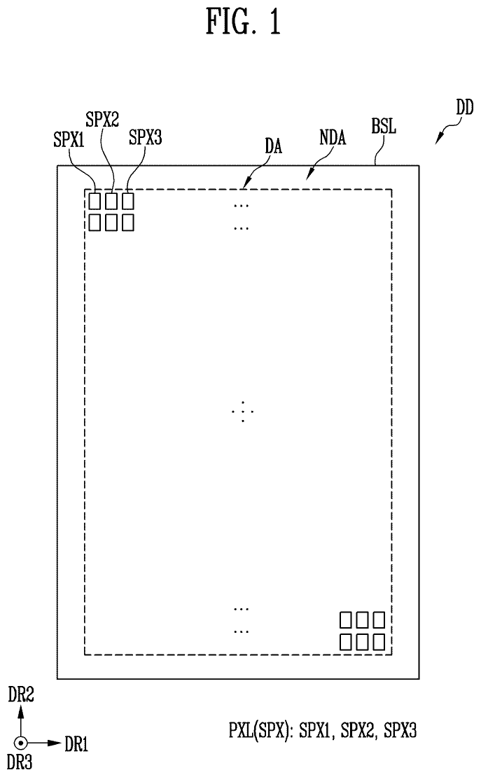

FIG. 1 illustrates a schematic top plan view of a display device according to an embodiment.

Referring to FIG. 1, a display device DD may include a base layer BSL, and a pixel PXL disposed on the base layer BSL. The display device DD may further include a driving circuit portion (for example, a scan driver and a data driver) for driving the pixel PXL, wires, and pads.

The display device DD (or the base layer BSL) may include a display area DA and a non-display area NDA. The non-display area NDA may be an area other than the display area DA. The non-display area NDA may surround at least a portion of the display area DA.

The base layer BSL may form a base surface of the display device DD. In some embodiments, the base layer BSL may be a lower substrate for disposing layers forming the display device DD. The base layer BSL may be a rigid substrate or film or a flexible substrate or film. For example, the base layer BSL may include a glass material. In another example, the base layer BSL may include a silicon material. In another example, the base layer BSL may include polyimide. However, embodiments are not limited thereto.

The display area DA may be an area in which the pixels PXL are disposed. The non-display area NDA may be an area in which the pixel PXL is not disposed. In the non-display area NDA, a driving circuit portion, wires, and pads connected to the pixel PXL of the display area DA may be disposed.

According to the embodiment, the pixel PXL (or sub-pixel SPX) may be arranged according to a stripe or pentile (PENTILE™) arrangement structure, but embodiments are not limited thereto, and various examples may be applied thereto.

According to the embodiment, the pixel PXL (or the sub-pixels SPX) may include the first sub-pixel SPX1, the second sub-pixel SPX2, and the third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and the third sub-pixel SPX3 may form a pixel unit capable of emitting light of various colors.

Each of the first sub-pixel SPX1, the second sub-pixel SPX2, and the third sub-pixel SPX3 may emit light of a color.

For example, the first sub-pixel SPX1 may be a red pixel emitting red (for example, first color) light, and the second sub-pixel SPX2 may be a green pixel emitting green (for example, second color) light, and the third sub-pixel SPX3 may be a blue pixel emitting blue (for example, third color) light. The red pixel may provide light in a wavelength band of about 600 nm to about 750 nm. The green pixel may provide light in a wavelength band of about 480 nm to about 560 nm. The blue pixel may provide light in a wavelength band of about 370 nm to about 460 nm.

According to the embodiment, the number of the second sub-pixels SPX2 may be greater than the number of the first sub-pixels SPX1 and the number of the third sub-pixels SPX3. However, the color, type, and/or number of the first sub-pixel SPX1, the second sub-pixel SPX2, and the third sub-pixel SPX3 forming each pixel unit described above are not limited thereto.

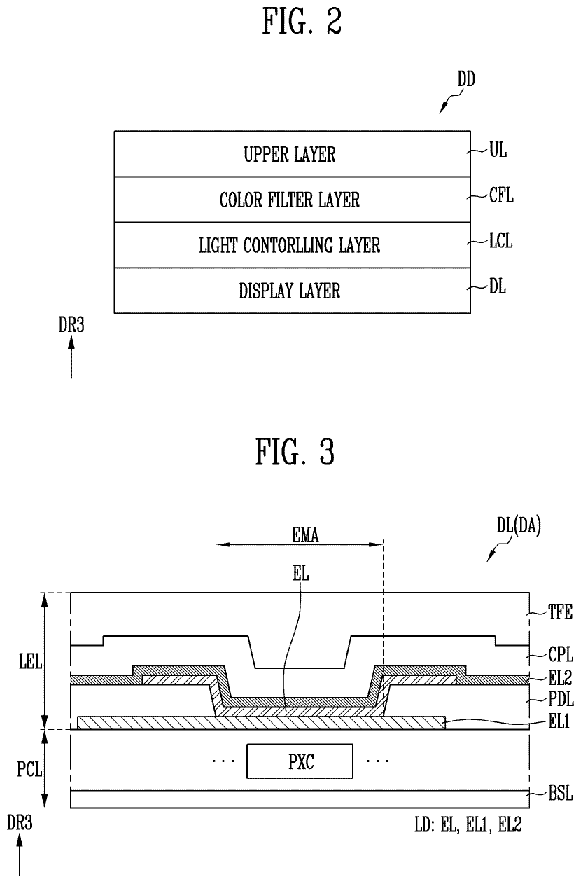

A general structure including a cross-sectional structure of the display device DD according to the embodiment will be described with reference to FIG. 2 and FIG. 3.

FIG. 2 illustrates a schematic cross-sectional view of a display device according to an embodiment. FIG. 3 illustrates a schematic view of a display layer according to an embodiment.

Referring to FIG. 2 and FIG. 3, the display device DD may include a display layer DL, a light controlling layer LCL, a color filter layer CFL, and an upper layer UL.

The display layer DL may emit light. The display layer DL may form a base on which the light controlling layer LCL is disposed.

The display layer DL may include a pixel circuit layer PCL including the base layer BSL, and a light emitting element layer LEL including a light emitting element LD to be able to form the pixel PXL.

The base layer BSL may form a base on which a pixel circuit PXC is disposed. The pixel circuit PXC may be disposed on the base layer BSL and may drive the light emitting element LD. The pixel circuit layer PCL may include conductive layers and insulating layers, and the conductive layers may form the pixel circuit PXC. The pixel circuit PXC may include circuit elements capable of driving the sub-pixel SPX (or the light emitting element LD). The circuit elements may include a driving transistor, and may also include additional transistors and capacitors.

The light emitting element layer LEL may be disposed on the pixel circuit layer PCL. In some embodiments, the light emitting element layer LEL may include the light emitting element LD.

For example, the light emitting element LD may include an organic light emitting diode (OLED) including an organic material. FIG. 3 schematically illustrates an embodiment in which the light emitting element LD is an organic light emitting diode, and a cross-sectional structure of the display device DD in the display area DA, which schematically shows a cross-sectional structure of the display layer DL including the pixel circuit layer PCL and the light emitting element layer LEL.

In some embodiments, the light emitting element layer LEL may further include a pixel defining layer PDL, a capping layer CPL, and an encapsulation layer TFE.

In some embodiments, the light emitting element LD may be disposed on the pixel circuit layer PCL. The light emitting element LD may include a first light emitting element included in the first sub-pixel SPX1, a second light emitting element included in the second sub-pixel SPX2, and a third light emitting element included in the third sub-pixel SPX3.

In some embodiments, the light emitting element LD may include a first electrode EL1, a light emitting portion EL, and a second electrode EL2. In some embodiments, the light emitting portion EL may be disposed in an area defined by the pixel defining layer PDL. A surface of the light emitting portion EL may be electrically connected to the first electrode EL1, and the other surface of the light emitting portion EL may be electrically connected to the second electrode EL2.

In some embodiments, the light emitting element LD may form a light emitting area EMA. The light emitting area EMA may be an area in which light emitted by the light emitting element LD is provided. In some embodiments, the light emitting area EMA may correspond to (or overlap) an area in which the first electrode EL1 is exposed by the pixel defining layer PDL. However, embodiments are not limited thereto.

The first electrode EL1 may be an anode electrode for the light emitting portion EL, and the second electrode EL2 may be a cathode electrode for the light emitting portion EL. In some embodiments, the first electrode EL1 and the second electrode EL2 may include a conductive material. For example, the conductive material may include one or more of gold (Au), silver (Ag), aluminum (Al), molybdenum (Mo), chromium (Cr), titanium (Ti), nickel (Ni), neodymium (Nd), copper (Cu), and platinum (Pt). In some embodiments, the conductive material may include one or more of a silver nanowire (AgNW), an indium tin oxide (ITO), an indium zinc oxide (IZO), an indium gallium zinc oxide (IGZO), an antimony zinc oxide (AZO), a zinc oxide (ZnO), a tin oxide (SnO₂), a carbon nano tube, and graphene. However, embodiments are not limited thereto.

The light emitting portion EL may emit light based on an electrical signal provided from the anode electrode (for example, the first electrode EL1) and the cathode electrode (for example, the second electrode EL2).

The light emitting portion EL may include a multi-layered structure. For example, each light emitting portion EL may include light emitting structures including a hole transport portion, a light emitting layer (or a light generation layer), and an electron transport portion. Respective layers forming the light emitting structure may include an organic material, and in some embodiments, they may further include an inorganic material such as a metal-containing compound or quantum dot.

In some embodiments, the light emitting portion EL may not include a light component of the second color and may emit light of a third color including a light component of the third color. For example, the light emitting structures may include a multilayer structure emitting light of the third color. Accordingly, the light emitted by the light emitting portion EL may be light of the third color.

In some embodiments, the light emitting portion EL may include a tandem structure. For example, the light emitting portion EL may emit light of one color including the light component of the second color and the light component of the third color. For example, the light emitting structures may include a first light emitting structure and a second light emitting structure. The first light emitting structure may include a multilayer structure that emits light of the second color. The second light emitting structure may include a multilayer structure that emits light of the third color. Accordingly, the light emitted by the light emitting portion EL may be a mixture of the second color and the third color.

The hole transport portion may include a multi-layered structure having a plurality of layers each including different materials. For example, the hole transport portion may include at least one of a hole injection layer and a hole transport layer, and in some embodiments, it may further include a light emitting auxiliary layer and an electron blocking layer. For example, the hole transport portion may have a multi-layered structure such as a hole injection layer/hole transport layer, a hole injection layer/hole transport layer/light emitting auxiliary layer, a hole transport layer/light emitting auxiliary layer, an electron blocking layer/hole injection layer/hole transport layer, hole transport layers that are sequentially disposed and include different materials, or a hole injection layer/hole transport layer/electron blocking layer. However, embodiments are not limited thereto.

The light emitting layer may include a material emitting light of a color. The light emitting layer may include a host and a dopant. The host of the light emitting layer is a light emitting material that captures carriers (electrons and holes) for light generation, and may induce excitons to be efficiently generated. The dopant may include a phosphorescent dopant or a fluorescent dopant. In some embodiments, examples of the dopant are not particularly limited. In some embodiments, the dopant may include an organic material or a metal complex.

The electron transport portion may include a multi-layered structure having a plurality of layers each including different materials. The electron transport portion may include at least one of an electron injection layer and an electron transport layer, and in some embodiment, it may further include an electron buffer layer and a hole blocking layer. For example, the electron transport portion may have a multi-layered structure such as an electron transport layer/electron injection layer, a hole blocking layer/electron transport layer/electron injection layer, an electron control layer/electron transport layer/electron injection layer, or a buffer layer/electron transport layer/electron injection layer. However, embodiments are not limited thereto.

The pixel defining layer PDL may be disposed on the pixel circuit layer PCL to define a position at which the light emitting portion EL is disposed. The pixel defining layer PDL may include an organic material. For example, the pixel defining layer PDL may include one or more of an acrylic resin, an epoxy resin, a phenol resin, a polyamide resin, and a polyimide resin. However, embodiments are not limited thereto. In another embodiment, the pixel defining layer PDL may include an inorganic material. For example, the pixel defining layer PDL may include one or more of a silicon oxide (SiOₓ) and a silicon nitride (SiNₓ). In some embodiments, the pixel defining layer PDL may have a multi-layered structure in which a layer including a silicon oxide (SiOₓ) and a layer including a silicon nitride (SiNₓ) are stacked.

The capping layer CPL may be disposed on the second electrode EL2. The capping layer CPL may cap the second electrode EL2. The capping layer CPL may include an inorganic material.

The encapsulation layer TFE may be disposed on the light emitting element LD (for example, the second electrode EL2). The encapsulation layer TFE may offset a level difference generated by the light emitting element LD and the pixel defining layer PDL. The encapsulation layer TFE may include insulating films covering the light emitting element LD. In some embodiments, the encapsulation layer TFE may have a structure in which an inorganic film and an organic film are alternately stacked with each other. In some embodiments, the encapsulation layer TFE may be a thin encapsulation film.

In some embodiments, the light emitting element LD may be an inorganic light emitting diode including an inorganic material. For example, as described above, the light emitting element LD may emit light of the third color, and, in some embodiments, the light emitting element LD may emit light including a light component of the second color and a light component of the third color.

The light controlling layer LCL may be disposed on the display layer DL (for example, light emitting element layer LEL). For example, the light controlling layer LCL may be disposed on an upper side of the display layer DL in a display direction (for example, third direction DR3).

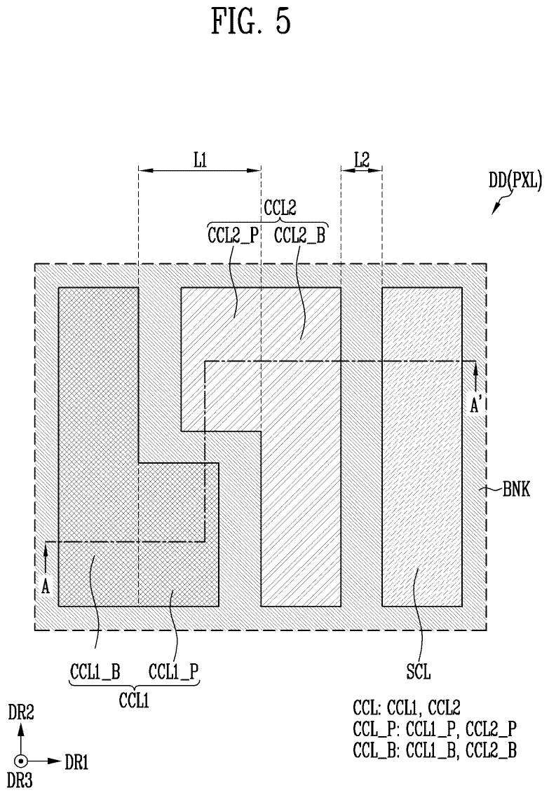

In some embodiments, the light controlling layer LCL may change the color of the applied light and may be a layer that scatters the applied light. For example, the light controlling layer LCL may include a color conversion layer CCL (see FIG. 5) and a scattering layer SCL (see FIG. 5).

The color filter layer CFL may be disposed on the light controlling layer LCL. For example, the color filter layer CFL may be disposed on the upper side of the light controlling layer LCL in the display direction (for example, third direction DR3).

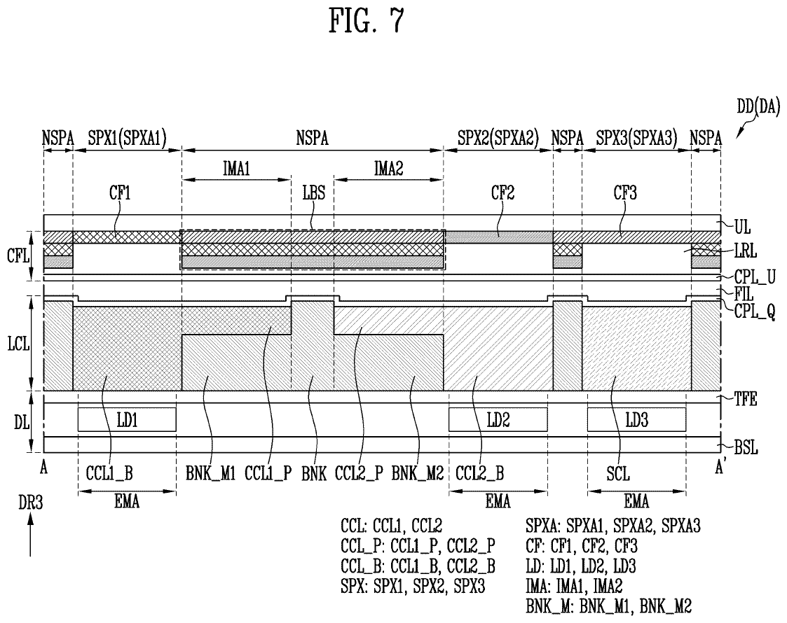

In some embodiments, the color filter layer CFL may include color filters CF (FIG. 7) that selectively transmit light of a color.

The upper layer UL may be disposed on the color filter layer CFL. For example, the upper layer UL may be disposed on an upper side of the color filter layer CFL in the display direction (for example, third direction DR3).

In some embodiments, the upper layer UL may include an upper substrate (for example, glass substrate). In another example, the upper layer UL may include an upper film layer. However, embodiments are not limited thereto.

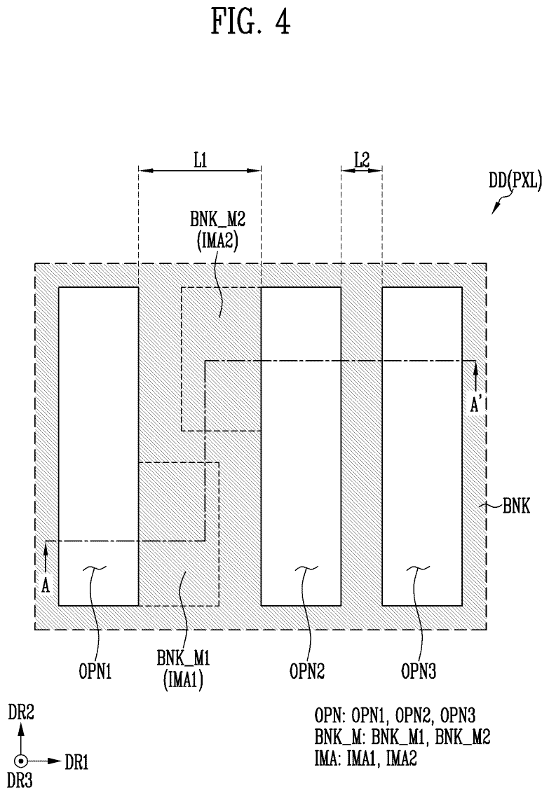

The display device DD according to the embodiment will be described with reference to FIG. 4 to FIG. 13. Redundant descriptions are simplified or are not repeated for descriptive convenience.

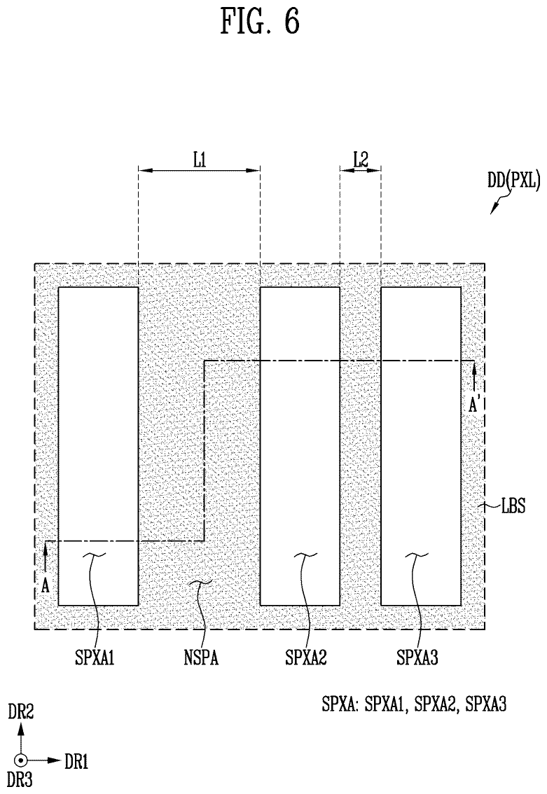

FIG. 4 to FIG. 6 illustrate schematic top plan views of a display device according to an embodiment. FIG. 7 illustrates a schematic cross-sectional view taken along line A-A′ of FIG. 4 to FIG. 6. FIG. 4 to FIG. 6 illustrate the pixels PXL and a same area. FIG. 4 schematically illustrates a bank BNK and a middle bank part BNK_M. FIG. 5 schematically illustrates a bank BNK, a color conversion layer CCL, and a scattering layer SCL. FIG. 6 schematically illustrates a light blocking member LBS. Based on FIG. 4 to FIG. 6, a disposition relationship of the components will be more clearly understood.

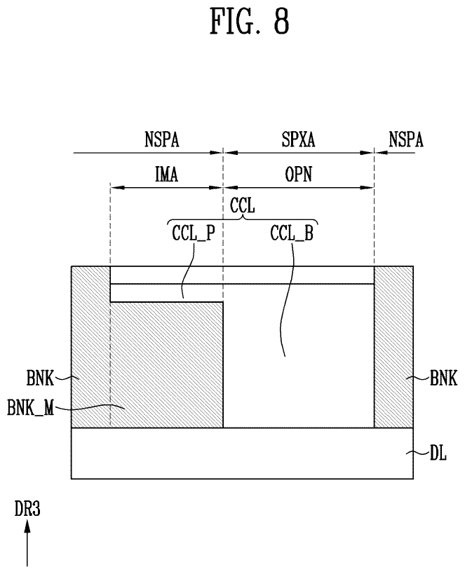

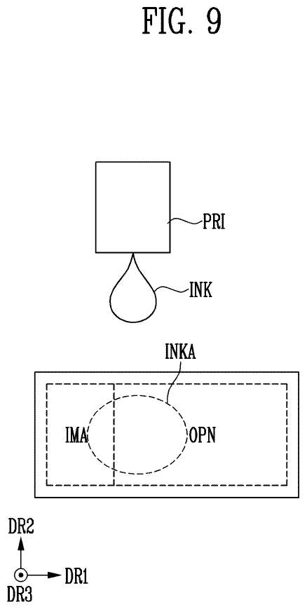

FIG. 8 and FIG. 10 to FIG. 13 illustrate schematic cross-sectional views of a structure formed by a bank and a middle bank part according to an embodiment. FIG. 9 illustrates a schematic top plan view of a step of performing an inkjet printing process among steps of a method of manufacturing a display device according to an embodiment.

Referring to FIG. 4 to FIG. 8, the display device DD (for example, the pixel PXL) may include the bank BNK and a middle bank part BNK_M.

The bank BNK and the middle bank part BNK_M may be patterned in the display area DA. The bank BNK and the middle bank part BNK_M may not be disposed in a partial area in the display area DA. For example, the bank BNK and the middle bank part BNK_M may form an opening OPN. The bank BNK and the middle bank part BNK_M may protrude in the thickness direction (for example, third direction DR3) of the base layer BSL and may surround the opening OPN. The bank BNK and the middle bank part BNK_M may expose the display layer DL (for example, the encapsulation layer TFE) in the opening OPN. The bank BNK and the middle bank part BNK_M may not be disposed in the opening OPN.

The bank BNK and the middle bank part BNK_M may be adjacent (e.g., directly adjacent) to each other. The bank BNK and the middle bank part BNK_M may be integral with each other. The bank BNK and the middle bank part BNK_M may be formed by a same process, and may include a same material. For example, the bank BNK and the middle bank part BNK_M may include one or more of an acrylic resin, an epoxy resin, a phenol resin, a polyamide resin, and a polyimide resin. In some embodiments, the bank BNK may include a light blocking material (for example, black matrix). However, embodiments are not limited thereto.

In some embodiments, an inkjet margin area IMA may be formed in the display area DA. The inkjet margin area IMA may correspond to the position of the middle bank part BNK_M. The inkjet margin area IMA may overlap the middle bank part BNK_M in a plan view. The inkjet margin area IMA may not overlap the bank BNK in a plan view.

The plan view defined in the description is a direction extending in the first direction DR1 and the second direction DR2, and may be defined based on a plane on which the base layer BSL is disposed. In some embodiments, a third direction DR3 may be a thickness direction of the base layer BSL, and the third direction DR3 may be a light emitting direction of the display device DD.

The opening OPN may include a first opening OPN1, a second opening OPN2, and a third opening OPN3. In some embodiments, the first opening OPN1 may be included in the first sub-pixel SPX1 and, in a plan view, may overlap a first sub-pixel area SPXA1. The second opening OPN2 may be included in the second sub-pixel SPX2 and, in a plan view, may overlap a second sub-pixel area SPXA2. The third opening OPN3 may be included in the third sub-pixel SPX3 and, in a plan view, may overlap a third sub-pixel area SPXA3.

The middle bank part BNK_M may include a first middle bank part BNK_M1 and a second middle bank part BNK_M2. In some embodiments, the first middle bank part BNK_M1 may be included in the first sub-pixel SPX1 and may not overlap the first sub-pixel area SPXA1 in a plan view. The second middle bank part BNK_M2 may be included in the second sub-pixel SPX2 and may not overlap the second sub-pixel area SPXA2 in a plan view.

The inkjet margin area IMA may include a first inkjet margin area IMA1 and a second inkjet margin area IMA2. In some embodiments, the first inkjet margin area IMA1 may be adjacent (e.g., directly adjacent) to the first opening OPN1 and may overlap the first middle bank part BNK_M1 in a plan view. The second inkjet margin area IMA2 may be adjacent (e.g., directly adjacent) to the second opening OPN2 and may overlap the second middle bank part BNK_M2 in a plan view.

The opening OPN and the inkjet margin area IMA may be adjacent (e.g., directly adjacent) to each other. In some embodiments, the first and second openings OPN1 and OPN2 and the inkjet margin area IMA may be areas in which ink INK (see FIG. 9) is supplied in/during an inkjet process of forming the color conversion layer CCL.

In some embodiments, the first to third openings OPN1 to OPN3 may be disposed along a first direction DR1. In some embodiments, the first middle bank part BNK_M1 and the second middle bank part BNK_M2 may overlap each other along a second direction DR2, which is different from the first direction DR1. The first inkjet margin area IMA1 and the second inkjet margin area IMA2 may overlap each other along the second direction DR2, which is different from the first direction DR1. The first inkjet margin area IMA1 and the second inkjet margin area IMA2 may overlap the first to third openings OPN1 to OPN3, respectively, along the first direction DR1.

In some embodiments, the first opening OPN1 and the second opening OPN2 may be spaced apart from each other by a first distance L1 in the first direction DR1 in a plan view. The second opening OPN2 and the third opening OPN3 may be spaced apart from each other by a second distance L2 in the first direction DR1 in a plan view. The first distance L1 may be larger than the second distance L2. This structure may be defined by forming the inkjet margin area IMA between the first opening OPN1 and the second opening OPN2. For example, the first and second inkjet margin areas IMA1 and IMA2 may be disposed in an area between some openings OPN, and a risk of an interval (or distance) between the openings OPN being excessively extended may be reduced.

The display device DD (for example, the pixel PXL) may include the color conversion layer CCL and the scattering layer SCL disposed in the display area DA.

The color conversion layer CCL may be patterned in the display area DA. The color conversion layer CCL may be disposed in an area surrounded by the bank BNK. In a plan view, the color conversion layer CCL may not overlap the bank BNK. In a plan view, the color conversion layer CCL may overlap the middle bank part BNK_M. A portion of the color conversion layer CCL may be disposed in the opening OPN. A portion of the color conversion layer CCL may be disposed in the inkjet margin area IMA.

The color conversion layer CCL may change the color of a color of light. For example, the color conversion layer CCL may include a first color conversion layer CCL1 and a second color conversion layer CCL2.

The first color conversion layer CCL1 may be a layer for forming the first sub-pixel SPX1. The first color conversion layer CCL1 may include first color conversion particles that convert light (for example, light including a light component of the third color) provided by the light emitting element LD into light of the first color. For example, the first color conversion layer CCL1 may include a first quantum-dot that converts light of the third color into light of the first color. The first quantum-dot may absorb light of the third color and shift the wavelength according to energy transition to emit light of the first color. The first quantum-dot may be dispersed and provided in a matrix layer such as an organic material included in the first color conversion layer CCL1.

The second color conversion layer CCL2 may be a layer for forming the second sub-pixel SPX2. The second color conversion layer CCL2 may include second color conversion particles that convert light (for example, light including a light component of the third color) provided by the light emitting element LD into light of the second color. For example, the second color conversion layer CCL2 may include a second quantum-dot that converts light of the third color into light of the second color. The second quantum-dot may absorb light of the third color and shift the wavelength according to energy transition to emit light of the second color. The second quantum-dot may be dispersed and provided in a matrix layer such as an organic material included in the second color conversion layer CCL2.

The color conversion layer CCL may include a base color conversion layer CCL_B and a protruding color conversion layer CCL_P. The base color conversion layer CCL_B and the protruding color conversion layer CCL_P may be integral with each other. The base color conversion layer CCL_B and the protruding color conversion layer CCL_P may be formed by a same inkjet process, and may include a same material.

The base color conversion layer CCL_B may be disposed in the opening OPN. In a plan view, the base color conversion layer CCL_B may not overlap the bank BNK and the middle bank part BNK_M.

The protruding color conversion layer CCL_P may be disposed in the inkjet margin area IMA. In a plan view, the protruding color conversion layer CCL_P may not overlap the bank BNK, but may overlap the middle bank part BNK_M.

In some embodiments, in a plan view, an area of the protruding color conversion layer CCL_P may be smaller than an area of the base color conversion layer CCL_B.

The base color conversion layer CCL_B may include a first base color conversion layer CCL1_B included in the first color conversion layer CCL1 and a second base color conversion layer CCL2_B included in the second color conversion layer CCL2.

The protruding color conversion layer CCL_P may include a first protruding color conversion layer CCL1_P included in the first color conversion layer CCL1 and a second protruding color conversion layer CCL2_P included in the second color conversion layer CCL2.

In some embodiments, the first protruding color conversion layer CCL1_P may be formed on a first side of the first base color conversion layer CCL1_B. The second protruding color conversion layer CCL2_P may be formed on a second side of the second base color conversion layer CCL2_B. The first side and the second side may be oriented in opposite directions. In some embodiments, the first protruding color conversion layer CCL1_P and the second protruding color conversion layer CCL2_P may overlap each other in the second direction DR2 in a plan view.

In some embodiments, the first base color conversion layer CCL1_B and the second base color conversion layer CCL2_B may be spaced apart from each other by the first distance L1 in the first direction DR1 in a plan view. In a plan view, the second base color conversion layer CCL2_B and the scattering layer SCL may be spaced apart from each other by the second distance L2 in the first direction DR1. The first distance L1 may be larger than the second distance L2.

The scattering layer SCL may be patterned in the display area DA. The scattering layer SCL may be disposed in an area surrounded by the bank BNK. In a plan view, the scattering layer SCL may not overlap the bank BNK.

The scattering layer SCL may be a layer for improving light emission efficiency of the display device DD and improving viewing angle characteristics. The scattering layer SCL may include scatterers. The scatterers may be dispersed and provided in a matrix layer such as an organic material (for example, a transparent organic material) included in the scattering layer SCL. In some embodiments, the scatterers may include various light scattering particles. For example, the scatterer may include one or more of a titanium oxide (TiOₓ), a silica (SiOₓ) (for example, a silica bead, a hollow silica, or the like), a zirconium oxide (ZrOₓ), an aluminum oxide (AlₓO_{y}), an indium oxide (InₓO_{y}), a zinc oxide (ZnOₓ), a tin oxide (SnOₓ), and an antimony oxide (SbₓO_{y}). However, embodiments are not limited thereto.

In some embodiments, the display device DD may include a sub-pixel area SPXA in which a color of light is provided and a non-sub-pixel area NSPA in which a color of light is not provided. The display device DD may include a light blocking member LBS.

The sub-pixel area SPXA may overlap the opening OPN in a plan view. In a plan view, the sub-pixel area SPXA may not overlap the inkjet margin area IMA. In a plan view, the non-sub-pixel area NSPA may overlap the inkjet margin area IMA.

In some embodiments, the sub-pixel area SPXA may include first to third sub-pixel areas SPXA1 to SPXA3. The first sub-pixel area SPXA1 may be an area in which light of the first color is provided, and may be an area in which the first base color conversion layer CCL1_B is disposed. The second sub-pixel area SPXA2 may be an area in which light of the second color is provided, and may be an area in which the second base color conversion layer CCL2_B is disposed. The third sub-pixel area SPXA3 may be an area in which light of the third color is provided, and may be an area in which the scattering layer SCL is disposed.

A portion of the color conversion layer CCL and the scattering layer SCL may be disposed in the sub-pixel area SPXA. For example, the base color conversion layer CCL_B may be disposed in the sub-pixel area SPXA, and the protruding base color conversion layer CCL_P may not be disposed in the sub-pixel area SPXA.

In some embodiments, the first sub-pixel area SPXA1 and the second sub-pixel area SPXA2 may be spaced apart from each other by the first distance L1 in the first direction DR1 in a plan view. In a plan view, the second sub-pixel area SPXA2 and the third sub-pixel area SPXA3 may be spaced apart from each other by the second distance L2 in the first direction DR1. The first distance L1 may be larger than the second distance L2.

In a plan view, the light blocking member LBS may not overlap the sub-pixel area SPXA and may be disposed in the non-sub-pixel area NSPA. Since the light blocking member LBS is formed, the risk of color mixing between the sub-pixels SPX may be reduced.

In some embodiments, the color conversion layer CCL may be formed by an inkjet process. At least a portion of the color conversion layer CCL may be provided in the opening OPN to form the sub-pixel area SPXA, and at least another portion of the color conversion layer CCL may be provided in the inkjet margin area IMA to be formed in the non-sub-pixel area NSPA. According to the embodiment, in order to perform the inkjet process, the inkjet margin area IMA forming a margin in which an ink drop is provided may be formed, but the inkjet margin area IMA may not correspond to (or may not overlap) the sub-pixel area SPXA. For example, the middle bank part BNK_M forming a relatively smaller accommodation space than the bank BNK may be formed in the inkjet margin area IMA. Accordingly, the amount of ink required for performing an inkjet process may be reduced, and process margins are secured or ensured, thus process convenience may be improved, and process costs may be reduced.

In some embodiments, the light controlling layer LCL, the color filter layer CFL, and the upper layer UL may be disposed on the display layer DL.

The light emitting element LD formed in the display layer DL may be disposed in each of the sub-pixel areas SPXA. For example, the light emitting element LD may include a first light emitting element LD1 included in the first sub-pixel SPX1 to be disposed in the first sub-pixel area SPXA1, a second light emitting element LD2 included in the second sub-pixel SPX2 to be disposed in the second sub-pixel area SPXA2, and a third light emitting element LD3 included in the third sub-pixel SPX3 to be disposed in the third sub-pixel area SPXA3.

In some embodiments, the first to third light emitting elements LD1 to LD3 may emit light including a light component of the third color. For example, the first to third light emitting elements LD1 to LD3 may emit light of the third color in a same manner. In some embodiments, the first to third light emitting elements LD1 to LD3 may emit light including a light component of the second color and a light component of the third color. For example, the first to third light emitting elements LD1 to LD3 may emit light of a color that is a mixture of a light component of the second color and a light component of the third color.

In some embodiments, the light emitting area EMA formed by the light emitting element LD may overlap the sub-pixel area SPXA in a plan view.

The light emitting area EMA (or the light emitting element LD) may overlap the base color conversion layer CCL_B and the color filter CF in a plan view. The light emitting area EMA (or the light emitting element LD) may overlap the scattering layer SCL and the color filter CF in a plan view. The light emitting area EMA (or the light emitting element LD) may not overlap the protruding color conversion layer CCL_P in a plan view.

In some embodiments, light provided by the first light emitting element LD1 may pass through the first base color conversion layer CCL1_B and the first color filter CF1 to be provided as light of the first color, and may form the first sub-pixel area SPXA1. Light provided by the second light emitting element LD2 may pass through the second base color conversion layer CCL2_B and the second color filter CF2 to be provided as light of the second color, and may form the second sub-pixel area SPXA2. Light provided by the third light emitting element LD3 may pass through the scattering layer SCL and the third color filter CF3 to be provided as light of the third color, and may form the third sub-pixel area SPXA3.

The light controlling layer LCL may be disposed on the display layer DL (for example, the encapsulation layer TFE). As described above, the light controlling layer LCL may include the color conversion layer CCL including the base color conversion layer CCL_B and the protruding color conversion layer CCL_P, the scattering layer SCL, the bank BNK, and the middle bank part BNK_M, and may further include a lower capping layer CPL_Q.

The bank BNK and the middle bank part BNK_M may expose an upper surface of the display layer DL (for example, an upper surface of the encapsulation layer TFE).

The bank BNK may have a higher height than the middle bank part BNK_M. In the description, the height of one component may be defined in a thickness direction (for example, the third direction DR3) of the base layer BSL. Accordingly, as described above, the volume of the protruding color conversion layer CCL_P disposed in the inkjet margin area IMA may not be excessively consumed.

In some embodiments, the first protruding color conversion layer CCL1_P may be disposed in the first inkjet margin area IMA1 defined in the non-sub-pixel area NSPA. The second protruding color conversion layer CCL2_P may be disposed in the second inkjet margin area IMA2 defined in the non-sub-pixel area NSPA.

In some embodiments, the volume of the protruding color conversion layer CCL_P may be smaller than the volume of the base color conversion layer CCL_B. For example, the volume of the first protruding color conversion layer CCL1_P may be smaller than the volume of the first base color conversion layer CCL1_B. The volume of the second protruding color conversion layer CCL2_P may be smaller than the volume of the second base color conversion layer CCL2_B.

As described above, the inkjet margin area IMA may be formed in the display device DD, and the process convenience of the inkjet process of forming the color conversion layer CCL may be improved. This will be described with reference to FIG. 9.

In some embodiments, in order to perform the inkjet process, an inkjet printer PRI may be prepared that provides an ink INK including a material for forming the color conversion layer CCL and includes a nozzle portion for ejecting the ink INK.

In some embodiments, the inkjet printer PRI may eject the ink INK to an area. For example, the area in which the ink INK provided by the inkjet printer PRI is ejected may be defined as an ink provision area INKA. In case that the inkjet process is performed, the ink provision area INKA may be formed across the inkjet margin area IMA and the opening OPN. For example, the ink provision area INKA may be formed across the inkjet margin area IMA and the opening OPN, and the ink INK supplied to the ink provision area INKA may be diffused to be disposed throughout the opening OPN and the inkjet margin area IMA. Accordingly, the base color conversion layer CCL_B and the protruding color conversion layer CCL_P may be formed.

Referring back to FIG. 7, the lower capping layer CPL_Q may cover other layers of the light controlling layer LCL. The lower capping layer CPL_Q may passivate the bank BNK, the color conversion layer CCL, and the scattering layer SCL. The lower capping layer CPL_Q may include an inorganic material.

In some embodiments, the display device DD may further include a filling layer FIL interposed between the light controlling layer LCL and the color filter layer CFL. The filling layer FIL may include various transparent organic materials, examples of which are not particularly limited. In some embodiments, a first panel in which the light controlling layer LCL is disposed on the display layer DL including the base layer BSL may be manufactured, a second panel in which the color filter layer CFL is disposed on the upper layer UL may be manufactured, and the filling layer FIL may be interposed between the first panel and the second panel so that the first panel and the second panel may be coupled to manufacture the display device DD. However, embodiments are not limited thereto.

The color filter layer CFL may be disposed on the light controlling layer LCL (for example, on the filling layer FIL). The color filter layer CFL may be formed under the upper layer UL. The color filter layer CFL may include color filters CF, an optical layer LRL, and an upper capping layer CPL_U.

According to the embodiment, the color filters CF may include a first color filter CF1 for forming the first sub-pixel SPX1, a second color filter CF2 for forming the second sub-pixel SPX2, and a third color filter CF3 for forming the third sub-pixel SPX3.

The first color filter CF1 may be disposed in the first sub-pixel area SPXA1. The first color filter CF1 may include a color filter material (for example, a dye or pigment) that selectively transmits light of the first color (for example, red).

The second color filter CF2 may be disposed in the second sub-pixel area SPXA2. The second color filter CF2 may include a color filter material (for example, a dye or pigment) that selectively transmits light of the second color (for example, green).

The third color filter CF3 may be disposed in the third sub-pixel area SPXA3. The third color filter CF3 may include a color filter material (for example, a dye or pigment) that selectively transmits light of the third color (for example, blue).

In some embodiments, the non-sub-pixel area NSPA in which light of a color is visually recognized may be formed between the sub-pixel areas SPXA. For example, in a plan view, in the non-sub-pixel area NSPA, the light blocking member LBS in which the first color filter CF1, the second color filter CF2, and the third color filter CF3 overlap may be formed.

The optical layer LRL may have a refractive index greater than those of layers forming the color filters CF. The optical layer LRL may have a refractive index smaller than that of the color conversion layer CCL, and may form an optical recycling structure.

The optical layer LRL may include various materials to have a refractive index. For example, the optical layer LRL may include various resins and hollow silica. In another example, the optical layer LRL may include a zirconium oxide (ZrOₓ). However, embodiments are not limited thereto. The optical layer LRL may have a refractive index lower than that of the color conversion layer CCL, and may form an optical recycling structure. In some embodiments, the optical layer LRL may be referred to as a low refractive index layer.

The upper capping layer CPL_U may be disposed on the optical layer LRL. The upper capping layer CPL_U may be disposed across the sub-pixel areas SPXA and the non-sub-pixel areas NSPA. The upper capping layer CPL_U may passivate the optical layer LRL. The upper capping layer CPL_U may include an inorganic material.

The upper layer UL may be disposed on the color filter layer CFL. The upper layer UL may be a substrate on which the color filter layer CFL is disposed, and in some embodiments, the upper layer UL may include a functional film layer (for example, an anti-reflection film, a polarizing film layer, or the like).

In some embodiments, the structure of the middle bank part BNK_M may be variously defined.

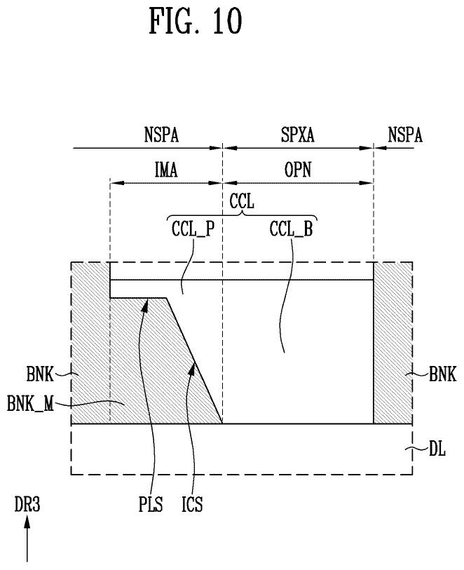

Referring to FIG. 10, the middle bank part BNK_M may have a trapezoidal cross section. For example, the middle bank part BNK_M may have a lower height than the bank BNK and may include an upper surface PLS and an inclined surface ICS that are substantially flat. The upper surface PLS may be oriented toward the third direction DR3, and the inclined surface ICS may be oriented toward the base color conversion layer CCL_B.

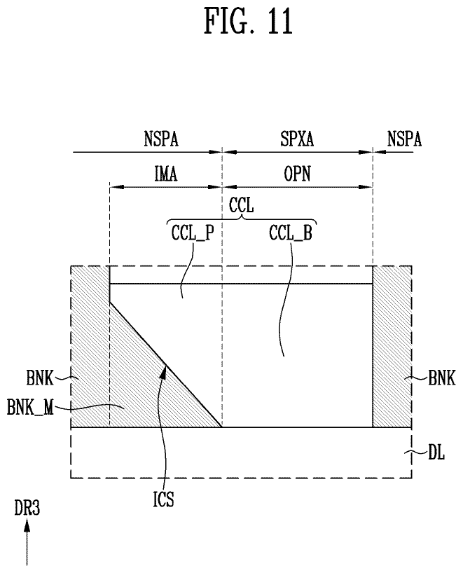

Referring to FIG. 11, the middle bank part BNK_M may have a triangular cross section. For example, the middle bank part BNK_M may include the inclined surface ICS without including a flat upper surface. An end portion of the inclined surface ICS may be adjacent to the bank BNK, and another end portion of the inclined surface ICS may be adjacent to the upper surface of the display layer DL.

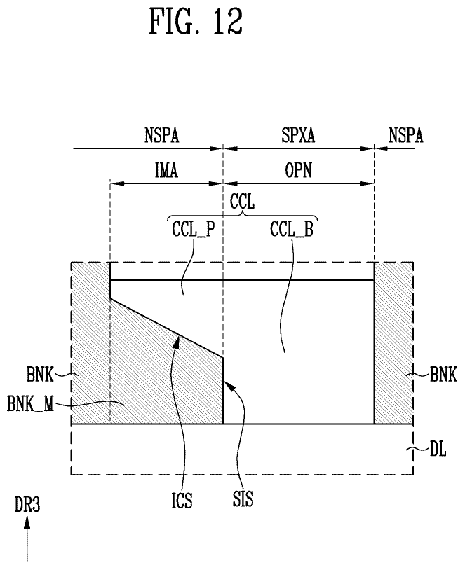

Referring to FIG. 12, the middle bank part BNK_M may have a trapezoidal cross section. For example, the middle bank part BNK_M may include an inclined surface ICS and a side surface SIS. The side surface SIS may be oriented toward the base color conversion layer CCL_B, and the inclined surface ICS may also be substantially oriented toward the base color conversion layer CCL_B. An end portion of the inclined surface ICS may be adjacent to the bank BNK. The side surface SIS may include a surface extending in the third direction DR3.

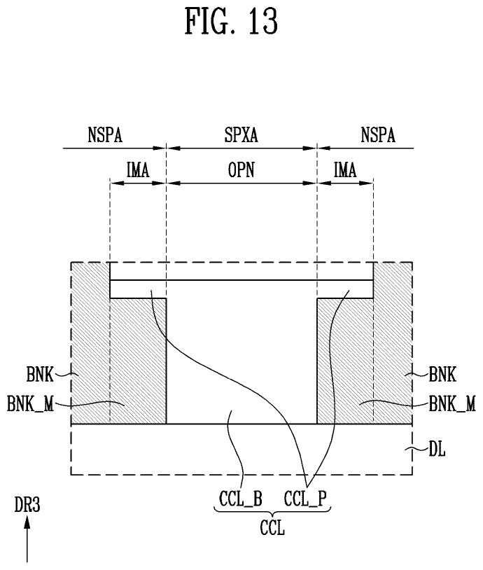

Referring to FIG. 13, the middle bank part BNK_M may include middle bank parts BNK_M. For example, a portion of the middle bank part BNK_M may be disposed on a side of the base color conversion layer CCL_B, and another portion of the middle bank part BNK_M may be disposed on another side of the base color conversion layer CCL_B.

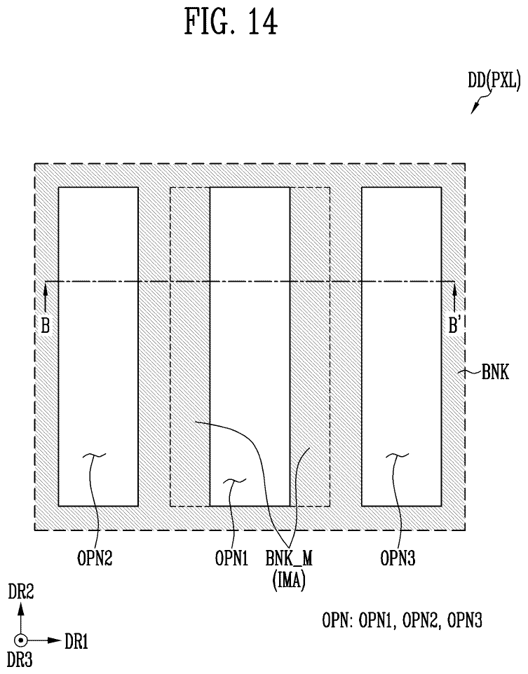

The display device DD according to another embodiment will be described with reference to FIG. 14 to FIG. 17. Redundant descriptions are simplified or are not repeated for descriptive convenience.

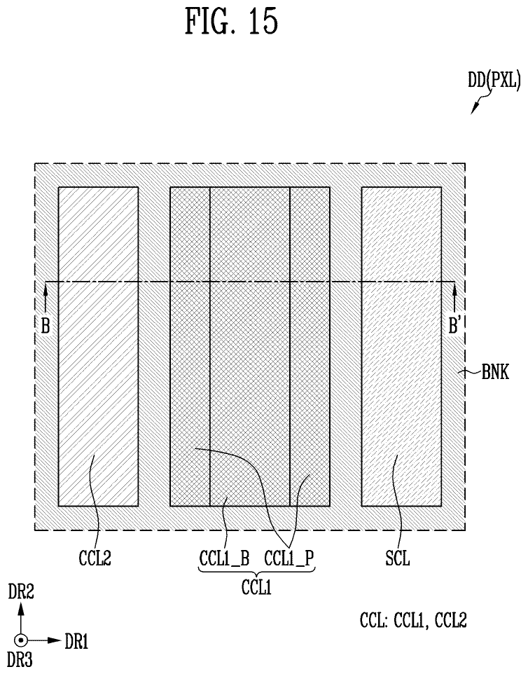

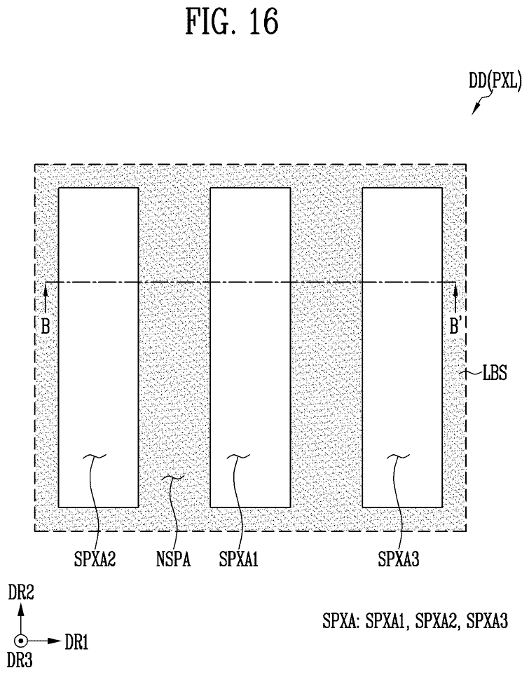

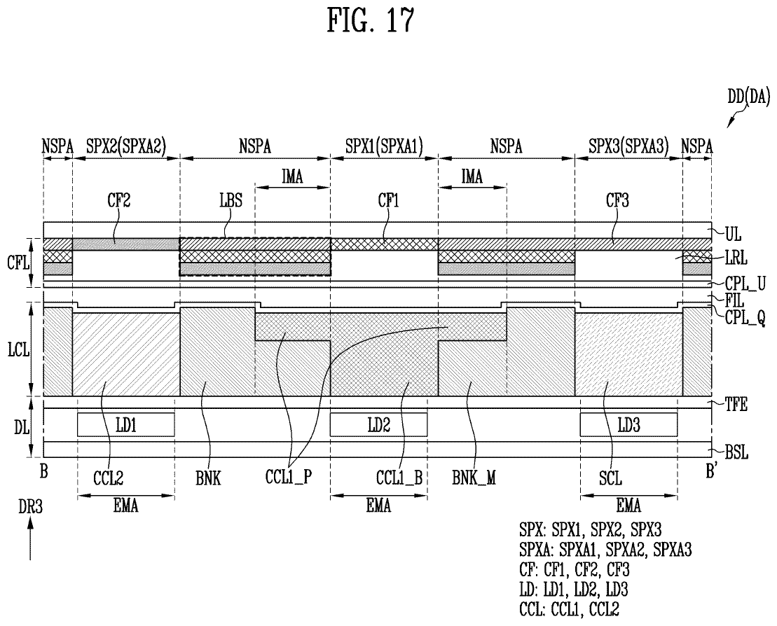

FIG. 14 to FIG. 16 illustrate schematic top plan views of a display device according to another embodiment. FIG. 17 illustrates a schematic cross-sectional view taken along line B-B′ of FIG. 14 to FIG. 16. FIG. 14 to FIG. 16 illustrate the pixels PXL and a same area. FIG. 14 schematically illustrates the bank BNK and the middle bank part BNK_M. FIG. 15 schematically illustrates the bank BNK, the color conversion layer CCL, and the scattering layer SCL. FIG. 16 schematically illustrates the light blocking member LBS. Based on FIG. 14 to FIG. 16, a disposition relationship of the components will be more clearly understood.

Referring to FIG. 14 to FIG. 17, the display device DD according to another embodiment is different from the display device DD according to the above-described embodiment in that the protruding color conversion layer CCL_P is formed only in the area corresponding to the first sub-pixel SPX1.

In some embodiments, the middle bank part BNK_M may be formed in an area adjacent (e.g., directly adjacent) to the first opening OPN1, and accordingly, the inkjet margin area IMA adjacent (e.g., directly adjacent) to the first opening OPN1 may be formed. The middle bank part BNK_M may not be formed in an area adjacent (e.g., directly adjacent) to the second opening OPN2, and the second opening OPN2 may be surrounded (e.g., entirely surrounded) by the bank BNK in a plan view.

In some embodiments, the first color conversion layer CCL1 may be disposed in the first opening OPN1 and the inkjet margin area IMA. For example, the first color conversion layer CCL1 may include a first base color conversion layer CCL1_B in the first opening OPN1 and a first protruding color conversion layer CCL1_P in the inkjet margin area. The second color conversion layer CCL2 may be disposed in the second opening OPN2 without being disposed in the inkjet margin area IMA. The scattering layer SCL may be disposed in the third opening OPN3.

In some embodiment, the inkjet margin area IMA adjacent to the first opening OPN1 may overlap the non-sub-pixel area NSPA in a plan view.

In some embodiments, the first to third sub-pixel areas SPXA1 to SPXA3 may be spaced apart from each other in the first direction DR1. The first sub-pixel area SPXA1 may be disposed between the second sub-pixel area SPXA2 and the third sub-pixel area SPXA3.

For example, the middle bank part BNK_M may include middle bank parts BNK_M, and the middle bank parts BNK_M may be disposed on a side and another side of the first opening OPN1, respectively. Accordingly, the inkjet margin area IMA may be formed on a side and another side of the first opening OPN1. Accordingly, the first protruding color conversion layer CCL1_P may include first protruding color conversion layers CCL1_P. Some of the first protruding color conversion layers CCL1_P may be disposed on a side of the first base color conversion layer CCL1_B, and the others of the first protruding color conversion layers CCL1_P may be disposed on another side of the first base color conversion layer CCL1_B.

According to the embodiment, the inkjet margin area IMA may be formed only in the area in which the first color conversion layer CCL1 is formed among the first and second color conversion layers CCL1 and CCL2. For example, the first sub-pixel area SPXA1 corresponding to the first opening OPN1 in which the inkjet margin area IMA is selectively formed may be formed between the second and third sub-pixel areas SPXA2 and SPXA3. Accordingly, in the embodiment, since the inkjet margin area IMA may be efficiently formed on sides (e.g., opposite sides) of the first opening OPN1, the ink provision area INKA may be further increased to provide a technical effect of further improving process convenience.

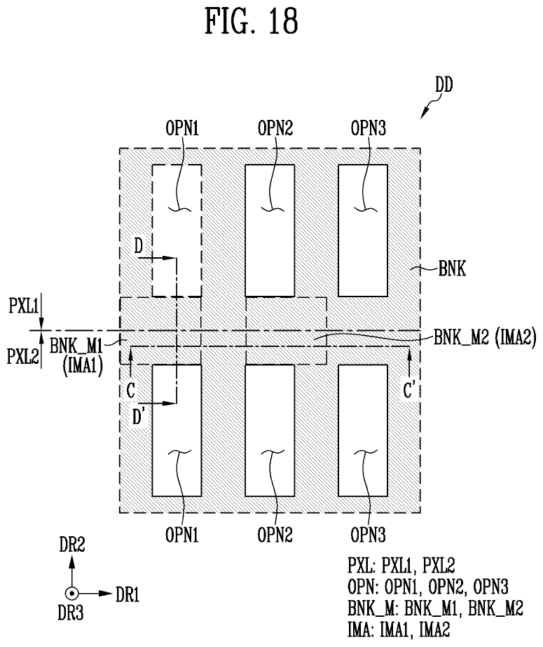

The display device DD according to another embodiment will be described with reference to FIG. 18 to FIG. 24. Redundant descriptions are simplified or are not repeated for descriptive convenience.

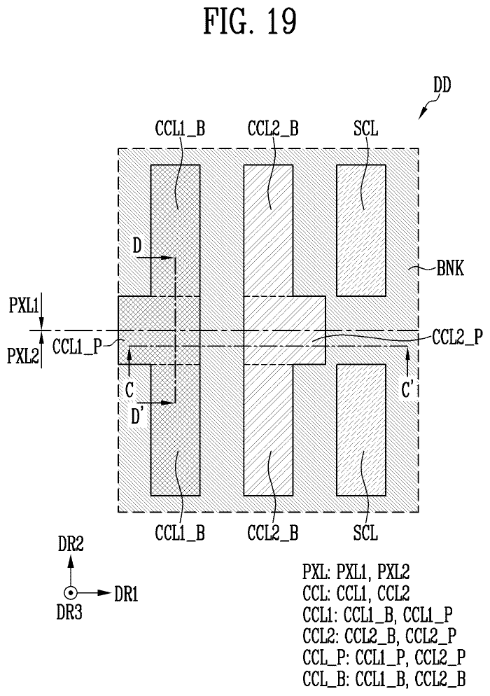

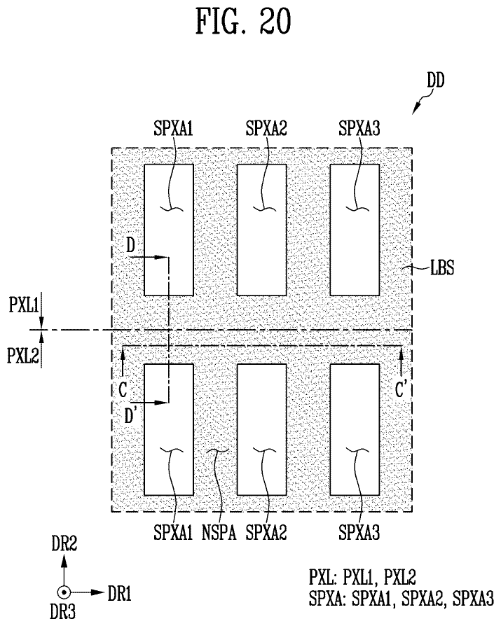

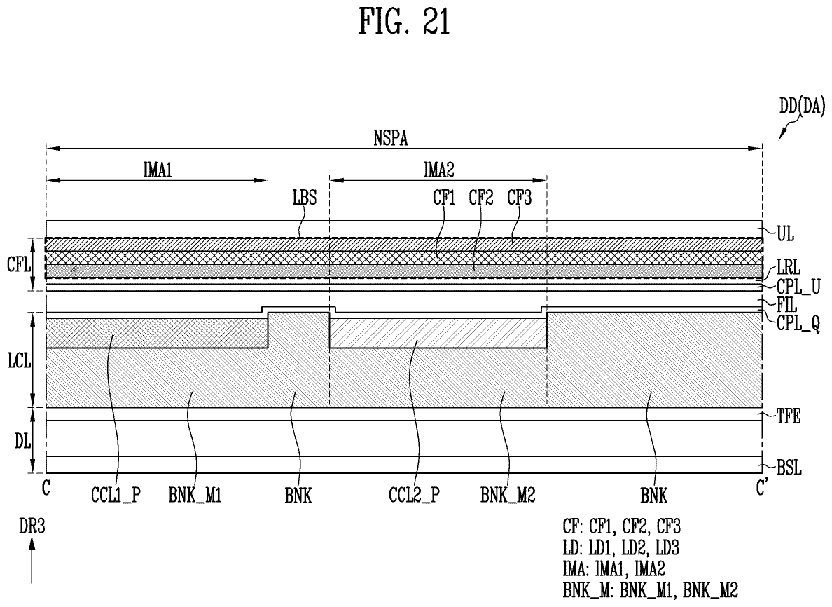

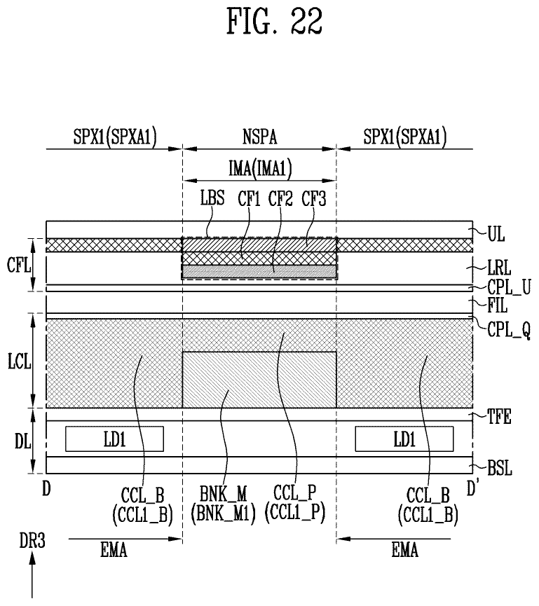

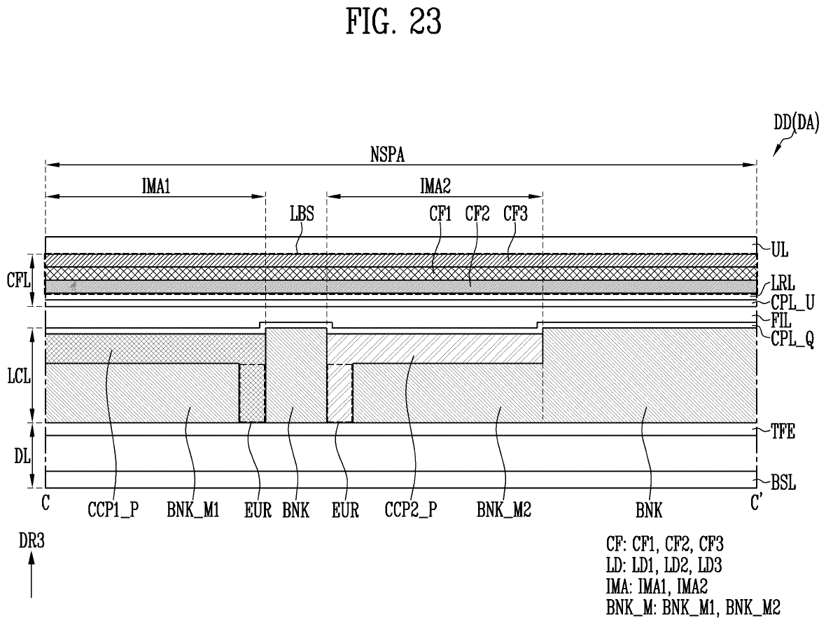

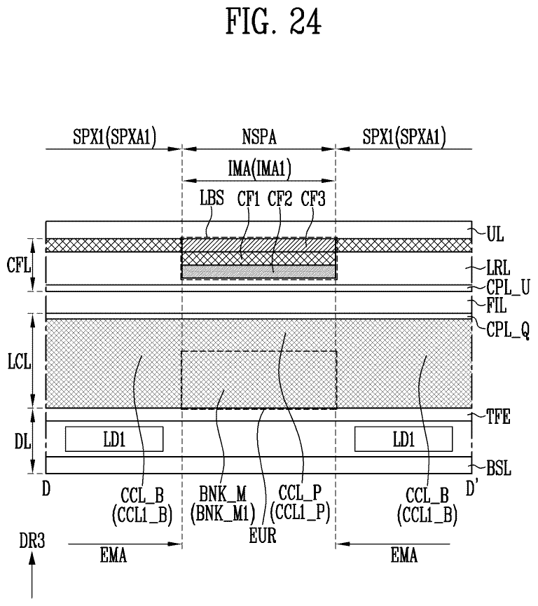

FIG. 18 to FIG. 20 illustrate schematic top plan views of a display device according to another embodiment. FIG. 21 and FIG. 23 illustrate schematic cross-sectional views taken along line C-C′ of FIG. 18 to FIG. 20. FIG. 22 and FIG. 24 illustrate schematic cross-sectional views taken along line D-D′ of FIG. 18 to FIG. 20. FIG. 18 to FIG. 20 illustrate the pixels PXL and a same area. FIG. 18 schematically illustrates the bank BNK and the middle bank part BNK_M. FIG. 19 schematically illustrates the bank BNK, the color conversion layer CCL, and the scattering layer SCL. FIG. 20 schematically illustrates the light blocking member LBS. Based on FIG. 18 to FIG. 20, a disposition relationship of the components will be more clearly understood.

Referring to FIG. 18 to FIG. 24, the display device DD according to another embodiment is different from the display device DD according to the above-described embodiment in that the inkjet margin area IMA is formed between the openings OPN respectively corresponding to the different pixels PXL.

In some embodiments, the first to third openings OPN1 to OPN3 may be adjacent to each other in the first direction DR1, and the first to third sub-pixel areas SPXA1 to SPXA3 may be adjacent to each other in the first direction DR1. In some embodiments, the pixel PXL may include a first pixel PXL1 and a second pixel PXL2 adjacent to each other along the second direction DR2 different from the first direction DR1.

In some embodiments, the middle bank part BNK_M may be disposed between the openings OPN respectively corresponding to the pixels PXL different from each other with respect to the second direction DR2. The inkjet margin area IMA may be disposed between the opening OPN of the first pixel PXL1 and the opening OPN of the second pixel PXL2 with respect to the second direction DR2. For example, the first inkjet margin area IMA1 may be disposed between the first opening OPN1 of the first pixel PXL1 and the first opening OPN1 of the second pixel PXL2. The second inkjet margin area IMA2 may be disposed between the second opening OPN2 of the first pixel PXL1 and the second opening OPN2 of the second pixel PXL2.

In some embodiments, the first and second inkjet margin areas IMA disposed between the openings OPN may overlap the non-sub-pixel area NSPA in a plan view.

In some embodiments, the protruding color conversion layer CCL_P may be disposed between the base color conversion layer CCL_B of the first pixel PXL1 and the base color conversion layer CCL_B of the second pixel PXL2. The first protruding color conversion layer CCL1_P may be disposed between the first base color conversion layer CCL1_B of the first pixel PXL1 and the first base color conversion layer CCL1_B of the second pixel PXL2. The second protruding color conversion layer CCL2_P may be disposed between the second base color conversion layer CCL2_B of the first pixel PXL1 and the second base color conversion layer CCL2_B of the second pixel PXL2.

In some embodiments, the first protruding color conversion layer CCL1_P may protrude from the first base color conversion layer CCL1_B to a side with respect to the first direction DR1. The second protruding color conversion layer CCL2_P may protrude from the second base color conversion layer CCL2_B to another side with respect to the first direction DR1.

According to the embodiment, the ink INK provided in the inkjet margin area IMA may be moved to each of the different pixels PXL1 and PXL2. For example, since the inkjet margin area IMA may be adjacent (e.g., directly adjacent) to the openings OPN corresponding to the different pixels PXL1 and PXL2, in case that the ink INK is supplied to the inkjet margin area IMA, the ink INK may be moved to the openings OPN corresponding to the different pixels PXL. Accordingly, the process steps may be simplified, and process convenience may be improved to reduce process costs.

According to the embodiment, although the openings OPN are formed relatively adjacent to each other, the inkjet process may be appropriately performed. As described above, since the range of the openings OPN may correspond to (or overlap) the range of the sub-pixel area SPXA, the display device DD according to the embodiment may be manufactured to have high-resolution display quality.

Referring to FIG. 23 and FIG. 24, a fluid passage EUR may be further formed so that the ink INK may be moved more precisely in the embodiment.

The fluid passage EUR may be formed in the non-sub-pixel area NSPA. The fluid passage EUR may be formed between the different pixels PXL1 and PXL2. The fluid passage EUR may extend in the second direction DR2.

The fluid passage EUR may be formed in the inkjet margin area IMA that is a portion of the non-sub-pixel area NSPA, and may be defined in an area in which the middle bank part BNK_M is not formed. For example, the fluid passage EUR may be surrounded by the bank BNK and the middle bank part BNK_M, and may overlap the light blocking member LBS in a plan view.

As described above, in the embodiment, the ink INK supplied to the inkjet margin area IMA may be moved to the openings OPN corresponding to the different pixels PXL1 and PXL2. Since the fluid passage EUR according to the embodiment may be defined in a relatively narrow area surrounded by the bank BNK and the middle bank part BNK_M, as the fluid passage EUR is formed, the ink INK supplied to the inkjet margin area IMA may be more efficiently supplied to the openings OPN corresponding to the different pixels PXL1 and PXL2.

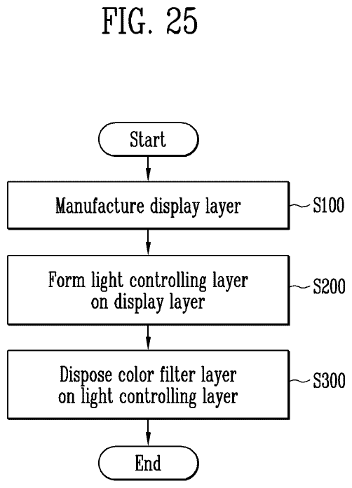

A method of manufacturing the display device DD according to the embodiment will be described with reference to FIG. 25 to FIG. 34. Redundant descriptions are simplified or are not repeated for descriptive convenience.

First, a method of manufacturing the display device DD according to the embodiment will be described with reference to FIG. 25 to FIG. 32. FIG. 25 to FIG. 32 illustrate a method of manufacturing the display device DD according to the embodiment illustrated in FIG. 4 to FIG. 13.

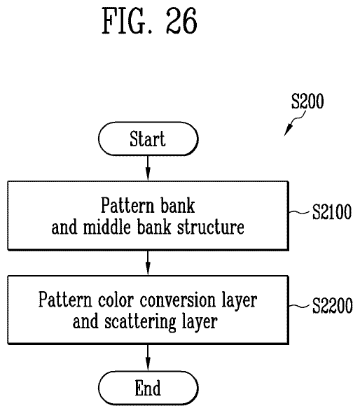

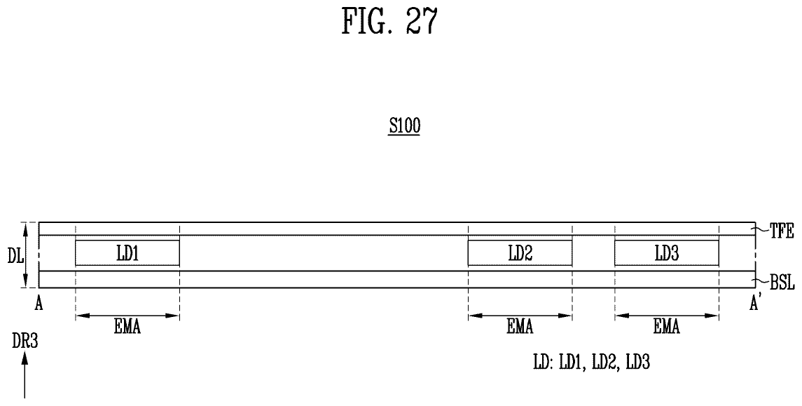

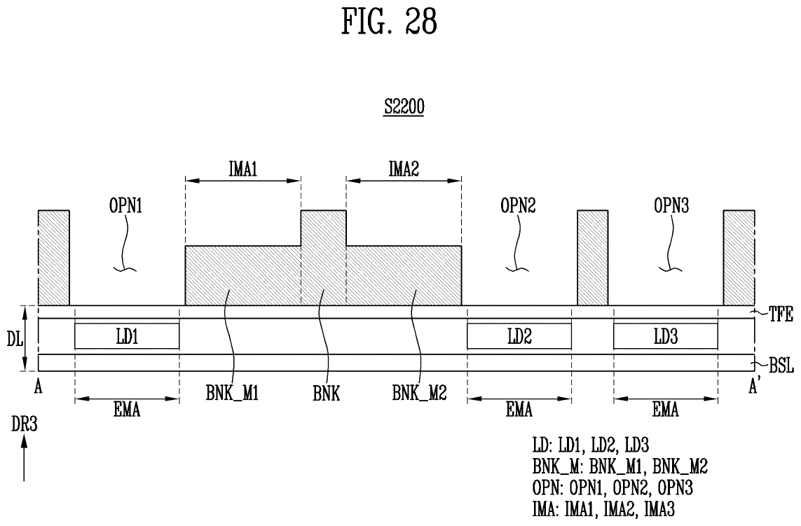

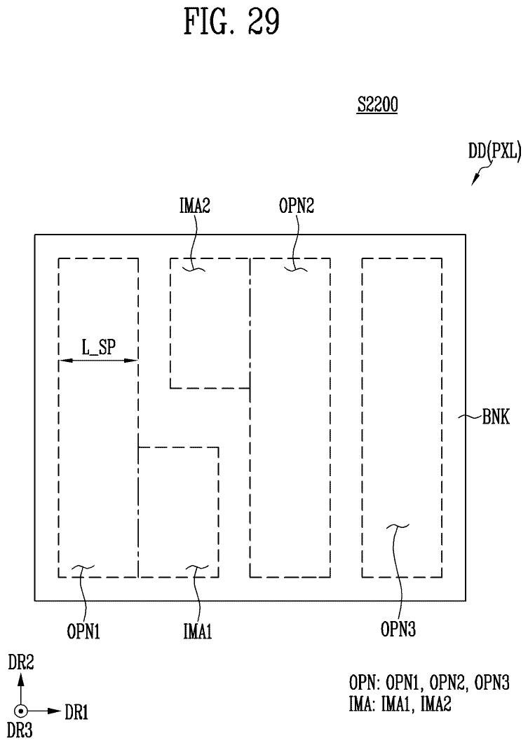

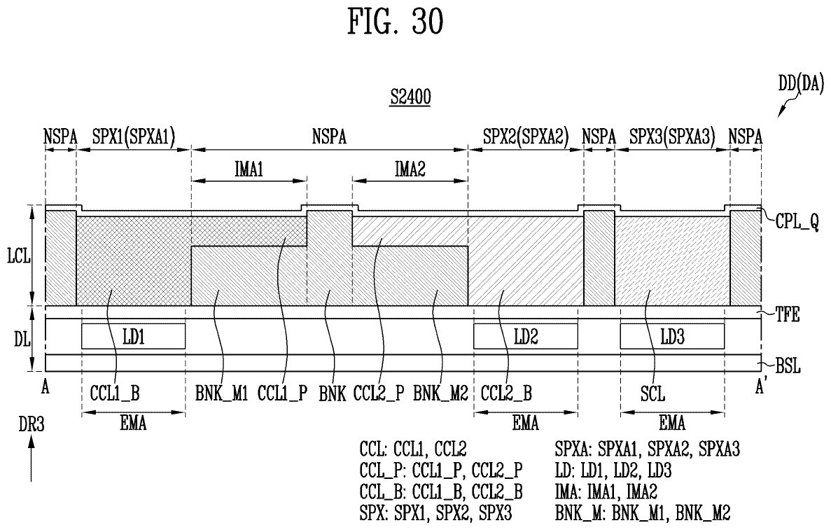

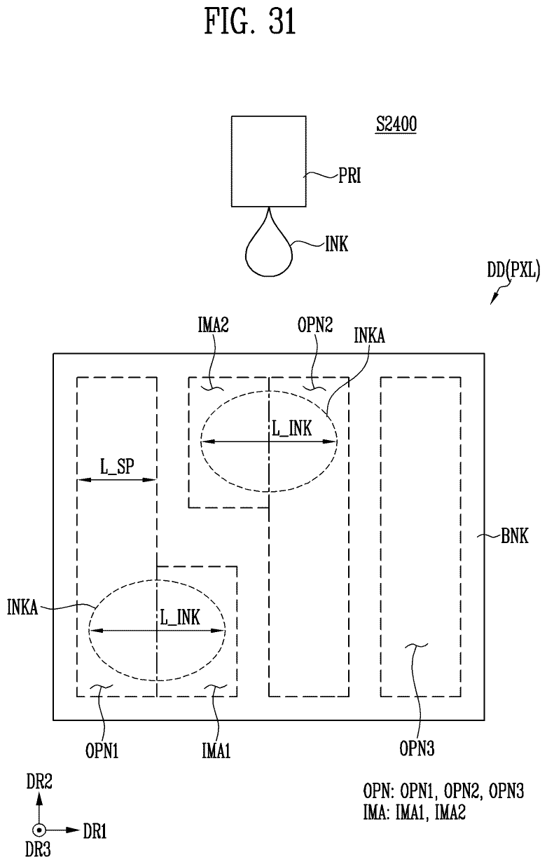

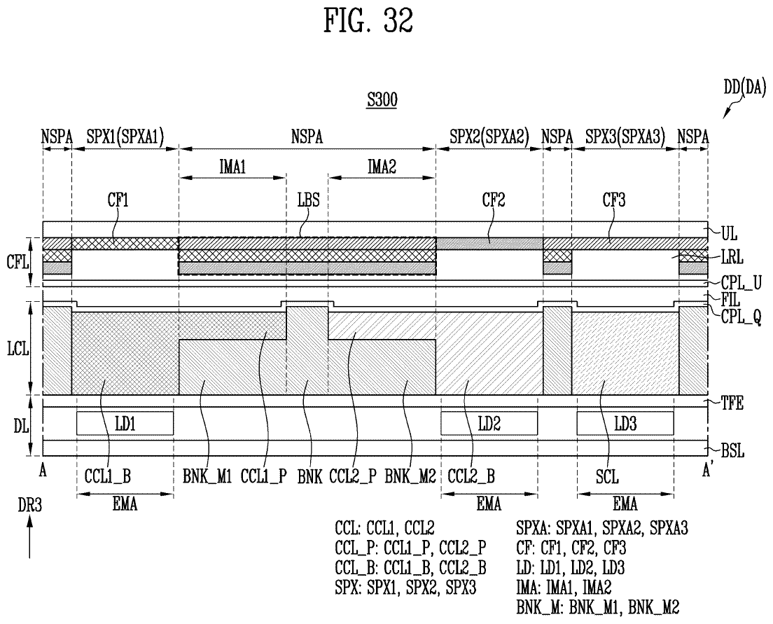

FIG. 25 illustrates a flowchart showing a method of manufacturing a display device according to an embodiment. FIG. 26 illustrates a flowchart showing steps of forming a light controlling layer on a display layer of FIG. 25. FIG. 27 to FIG. 32 illustrate schematic views of process steps of a method of manufacturing a display device according to an embodiment. FIG. 27, FIG. 28, FIG. 30, and FIG. 32 illustrate schematic cross-sectional views of respective process steps of a method of manufacturing the display device according to the embodiment illustrated based on the cross-sectional structure illustrated in FIG. 7. FIG. 29 and FIG. 31 illustrate schematic plan views of a step in which an inkjet printing process is performed among process steps of a method of manufacturing a display device according to an embodiment.

Referring to FIG. 25, the method of manufacturing the display device DD according to the embodiment may include manufacturing a display layer (S100), forming a light controlling layer on the display layer (S200), and disposing a color filter layer on the light controlling layer (S300).

Referring to FIG. 26, the forming of the light controlling layer on the display layer (S200) may include patterning a bank and a middle bank part (S2100) and patterning a color conversion layer and a scattering layer (S2200).

Referring to FIG. 25 and FIG. 27, in the manufacturing the display layer (S100), layers forming the display layer DL may be disposed on the base layer BSL.

In some embodiments, a conductive layer or an insulating layer on the base layer BSL may be formed by a process of manufacturing a semiconductor device. For example, the conductive layer or the insulating layer on the base layer BSL may be formed by a photolithography process, etched by various methods (e.g., a wet etching process, a dry etching process, and the like), and deposited by various methods (e.g., a sputtering process, a chemical vapor deposition process, and the like). However, embodiments are not limited to particular examples.

In the step S100, the pixel circuit PXC may be patterned on the base layer BSL, and the light emitting elements LD may be disposed. In some embodiments, in the step S100, the light emitting element LD may be disposed on the base layer BSL by various methods. For example, referring to FIG. 3 together, the light emitting element LD may include an organic light emitting diode, and the light emitting element LD may be manufactured on the base layer BSL by a deposition process. However, embodiments are not limited thereto.

In the step S100, the first light emitting element LD1 forming the first sub-pixel SPX1 and forming the light emitting area EMA, the second light emitting element LD2 forming the second sub-pixel SPX2 and forming the light emitting area EMA, and the third light emitting element LD3 forming the third sub-pixel SPX3 and forming the light emitting area EMA may be disposed, and the encapsulation layer TFE may be formed on the light emitting elements LD.

Referring to FIG. 25, FIG. 26, FIG. 28, and FIG. 29, in the forming of the light controlling layer on the display layer (S200), patterning the bank and the middle bank part (S2100) may be performed.

In the step S2200, the bank BNK and the middle bank part BNK_M forming the openings OPN may be formed on the display layer DL. The middle bank part BNK_M forming the inkjet margin area IMA may be formed on the display layer DL.

In some embodiments, the bank BNK and the middle bank part BNK_M may be formed by a same process. For example, after forming the layer for manufacturing the bank BNK and the middle bank part BNK_M, a positive photoresist layer may be disposed. For example, an etching mask may be provided by etching a positive photoresist layer disposed using a mask including a half-tone area and a full-tone area, and a process of etching at least a portion of the layer for manufacturing the bank BNK and the middle bank part BNK_M using the etching mask may be performed, thus the bank BNK and the middle bank part BNK_M may be manufactured. However, embodiments are not limited thereto. In some embodiments, the bank BNK and the middle bank part BNK_M may be manufactured using a slit-type mask, and the type of photoresist layer is not limited thereto.

In the step S2200, the first middle bank part BNK_M1 may be patterned to form the first inkjet margin area IMA1. The second middle bank part BNK_M2 may be patterned to form the second inkjet margin area IMA2. For example, the first to third openings OPN1 to OPN3 may be formed, the first inkjet margin area IMA1 may be formed to be adjacent (e.g., directly adjacent) to the first opening OPN1, and the second inkjet margin area IMA2 may be formed to be adjacent (e.g., directly adjacent) to the second opening OPN2.

In some embodiments, the first and second openings OPN1 and OPN2 may have an opening width L_SP in the first direction DR1. The opening width L_SP may be a width defined in the first and second openings OPN1 and OPN2 in a direction in which the first to third openings OPN1 to OPN3 are spaced apart from each other.

Referring to FIG. 25, FIG. 26, FIG. 30, and FIG. 31, in the forming of the light controlling layer on the display layer (S200), patterning the color conversion layer and the scattering layer (S2200) may be performed.

In the step S2400, the color conversion layer CCL may be formed by an inkjet process. For example, the inkjet printer PRI may discharge the ink INK for forming the color conversion layer CCL into the opening OPN and the inkjet margin area IMA, and accordingly, the color conversion layer CCL may be formed in the area surrounded by the bank BNK and the middle bank part BNK_M.

In some embodiments, a first inkjet process may be performed to provide (or form) the first base color conversion layer CCL1_B in the first opening OPN1, and to provide (or form) the first protruding color conversion layer CCL1_P in the first inkjet margin area IMA1. A second inkjet process may be performed to provide (or form) the second base color conversion layer CCL2_B in the second opening OPN2, and to provide (or form) the second protruding color conversion layer CCL2_P in the second inkjet margin area IMA2.

In some embodiments, the second color conversion layer CCL2 may be formed after the first color conversion layer CCL1 is formed, and in some embodiments, the first color conversion layer CCL1 may be formed after the second color conversion layer CCL2 is formed.

In the step S2400, the scattering layer SCL may be formed by a photolithography process. The scattering layer SCL may be formed in the third opening OPN3.

In some embodiments, the scattering layer SCL may be formed after the color conversion layer CCL is formed, and in some embodiments, the color conversion layer CCL may be formed after the scattering layer SCL is formed.

According to an embodiment, as described above, the ink provision area INKA to which the ink INK is discharged may be formed across the inkjet margin area IMA and the opening OPN. Accordingly, in order to perform the inkjet process, the range in which the ink INK is discharged may be more efficiently defined, so that a process margin of the inkjet process may be secured or ensured.

In some embodiments, the ink provision area INKA may have an ink area length L_INK. The ink area length L_INK may be the longest length defined in the ink provision area INKA. For example, in case that the ink provision area INKA has an elliptical shape, the ink area length L_INK may be a long radius.

In some embodiments, the ink area length L_INK may be greater than the opening width L_SP. Experimentally, in case that the inkjet margin area IMA is not formed, as the ink area length L_INK is greater than the opening width L_SP, the ink INK may leak (or overflow) to an area outside the opening OPN. However, according to the embodiment, the inkjet margin area IMA adjacent (e.g., directly adjacent) to the opening OPN is formed, so that the ink INK may be supplied to the opening OPN without leaking (or overflowing).

In some embodiments, after the color conversion layer CCL and the scattering layer SCL are disposed, the lower capping layer CPL_Q may be formed, and the color conversion layer CCL and the scattering layer SCL may be passivated.

Referring to FIG. 25 and FIG. 32, in the disposing of the color filter layer on the light controlling layer (S300), the color filters CF may be formed on the light controlling layer LCL.

In the step S300, layers for forming the color filter layer CFL on the upper layer UL may be patterned, and a filling layer FIL may be interposed between layers including the upper layer UL and the color filter layer CFL and the light controlling layer LCL. However, embodiments are not limited thereto.

In the step S300, the first to third color filters CF1 to CF3 may be patterned on the upper layer UL. The color filters CF may be formed by various processes, such as a photolithography process. In some embodiments, the formation order of the color filters CF is not limited thereto.

In the step S300, the optical layer LRL may be formed (or deposited) to cover the color filters CF, and the upper capping layer CPL_U may be formed on the optical layer LRL.

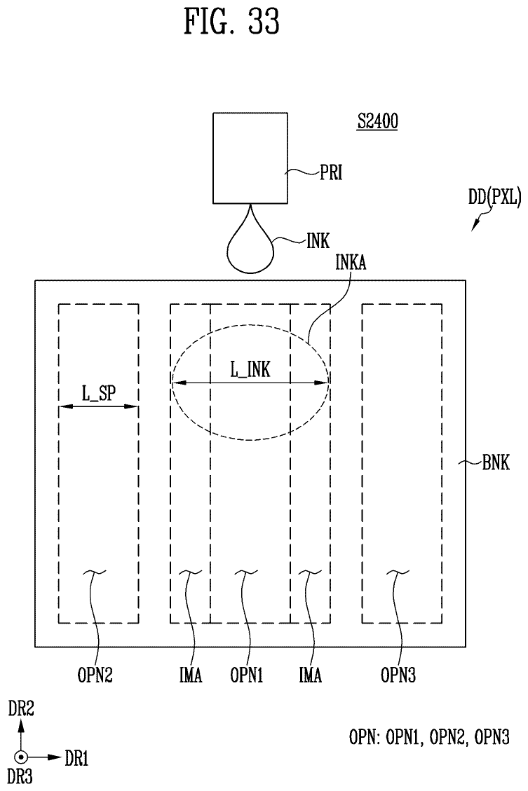

Referred to FIG. 33, a method of manufacturing the display device DD according to another embodiment will be described, focusing on different technical features compared to the method of manufacturing the display device DD described above. FIG. 33 illustrates a method of manufacturing the display device DD according to another embodiment illustrated in FIG. 14 to FIG. 17. FIG. 33 illustrates a schematic top plan view of a step of performing an inkjet printing process among process steps of a method of manufacturing a display device according to another embodiment.

Referring to FIG. 33, in the forming of the light controlling layer on the display layer (S200), patterning the color conversion layer and the scattering layer (S2200) may be performed, but the ink provision area INKA may be formed across the inkjet margin areas IMA and the first opening OPN1 spaced apart from each other.

For example, the inkjet margin area IMA may be formed to be adjacent (e.g., directly adjacent) to the first opening OPN1, and may be formed on sides (e.g., opposite sides) of the first opening OPN1, respectively. Accordingly, in case that the inkjet process is performed, the ink provision area INKA may be formed across the inkjet margin area IMA formed on a side of the first opening OPN1, the first opening OPN1, and the inkjet margin area IMA formed on another side of the first opening OPN1. In the embodiment as well, the ink area length L_INK may be larger than the opening width L_SP, and a process margin for the range in which the ink INK is discharged may be secured or ensured.

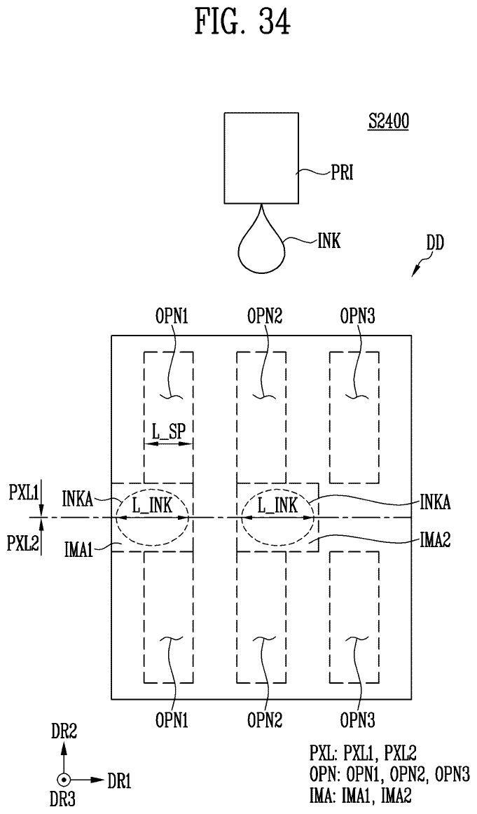

Referring to FIG. 34, a method of manufacturing the display device DD according to another embodiment will be described, focusing on different technical features compared to the method of manufacturing the display device DD described above. FIG. 34 illustrates a method of manufacturing the display device DD according to another embodiment illustrated in FIG. 18 to FIG. 24. FIG. 34 illustrates a schematic top plan view of a step of performing an inkjet printing process among process steps of a method of manufacturing a display device according to another embodiment.

Referring to FIG. 34, in the forming of the light controlling layer on the display layer (S200), patterning the color conversion layer and the scattering layer (S2200) may be performed, but the ink provision area INKA may be formed across the openings OPN of each of the different pixels PXL1 and PXL2 spaced apart from each other, and the inkjet margin area IMA.

Accordingly, although the inkjet printer PRI provides the ink INK to the inkjet margin area IMA, it may be moved to the opening OPN of each of the different pixels PXL1 and PXL2. For example, in the embodiment as well, the ink area length L_INK may be larger than the opening width L_SP, and a process margin for the range in which the ink INK is discharged may be secured or ensured.

While the disclosure has been shown and described with reference to certain embodiments thereof, it will be understood by those skilled in the art that various changes in forms and details may be made therein without departing from the spirit and scope of the disclosure as defined by the appended claims and their equivalents.

Therefore, the technical scope of the disclosure may be determined based on the technical scope of the accompanying claims.

What is claimed is:

1. A display device comprising:
a display layer; and
a light controlling layer disposed on the display layer, the light controlling layer including:
a bank,
a middle bank part directly adjacent to the bank, and
a color conversion layer, wherein
the light controlling layer includes an opening in which the bank and the middle bank part are not disposed, and
the color conversion layer includes:
a base color conversion layer disposed in at least a portion of the opening, and
a protruding color conversion layer overlapping the middle bank part in a plan view.

2. The display device of claim 1, wherein the bank has a height greater than the middle bank part.

3. The display device of claim 2, wherein
the base color conversion layer and the protruding color conversion layer are integral with each other and include a same material,
the bank and the middle bank part are integral with each other and includes a same material, and
the base color conversion layer has a larger volume than the protruding color conversion layer.

4. The display device of claim 1, further comprising:
a sub-pixel area in which light of a color is provided, and
a non-sub-pixel area adjacent to the sub-pixel area, wherein the sub-pixel area includes:
a first sub-pixel area in which light of a first color is provided,
a second sub-pixel area in which light of a second color is provided, and
a third sub-pixel area in which light of a third color is provided, the opening includes:
a first opening overlapping the first sub-pixel area in a plan view,
a second opening overlapping the second sub-pixel area in a plan view, and
a third opening overlapping the third sub-pixel area in a plan view, and the protruding color conversion layer overlaps the non-sub-pixel area in a plan view.

5. The display device of claim 4, wherein
the first opening and the second opening are spaced apart from each other by a first distance, and
the second opening and the third opening are spaced apart from each other by a second distance smaller than the first distance.

6. The display device of claim 5, wherein
the protruding color conversion layer includes:
a first protruding color conversion layer adjacent to the first sub-pixel area, and
a second protruding color conversion layer adjacent to the second sub-pixel area,
the first sub-pixel area, the second sub-pixel area, and the third sub-pixel area are adjacent to each other in a first direction, and
the first protruding color conversion layer and the second protruding color conversion layer overlap in a second direction different from the first direction.

7. The display device of claim 1, wherein the middle bank part includes:
an upper surface forming a lower height than the bank, and
an inclined surface facing the base color conversion layer.

8. The display device of claim 1, wherein the middle bank part includes:
an inclined surface having an end portion adjacent to the bank, and
another end portion adjacent to an upper surface of the display layer.

9. The display device of claim 1, wherein the middle bank part includes:
an inclined surface whose end portion is adjacent to the bank, and
a side surface facing the base color conversion layer.

10. The display device of claim 1, wherein the middle bank part includes:
a first middle bank part disposed on a side of the base color conversion layer, and
a second middle bank part disposed on another side of the base color conversion layer.

11. The display device of claim 1, further comprising:
a first sub-pixel providing a first color, a second sub-pixel providing a second color, and a third sub-pixel providing a third color; and
a scattering layer included in the third sub-pixel, wherein
the color conversion layer includes:
a first color conversion layer forming the first sub-pixel, and
a second color conversion layer forming the second sub-pixel, the base color conversion layer includes:
a first base color conversion layer included in the first color conversion layer, and
a second base color conversion layer included in the second color conversion layer, and
the protruding color conversion layer includes:
a first protruding color conversion layer included in the first color conversion layer, and
a second protruding color conversion layer included in the second color conversion layer.

12. The display device of claim 1, further comprising:
a first sub-pixel providing a first color, a second sub-pixel providing a second color, and a third sub-pixel providing a third color; and
a scattering layer included in the third sub-pixel,
wherein the protruding color conversion layer is formed in the second sub-pixel, without being formed in the first sub-pixel.

13. The display device of claim 12, wherein
the first sub-pixel is disposed between the second sub-pixel and the third sub-pixel,
the protruding color conversion layer includes a plurality of protruding color conversion layers, and
some of the plurality of protruding color conversion layers are disposed on a side of the base color conversion layer, and others of the plurality of protruding color conversion layers are disposed on another side of the base color conversion layer.

14. The display device of claim 1, further comprising:
pixels respectively including a plurality of sub-pixels forming a plurality of sub-pixel areas, wherein
the plurality of sub-pixel areas are spaced apart from each other in a first direction,
the pixels include a first pixel and a second pixel that are spaced apart from each other in a second direction different from the first direction, and
the middle bank part is disposed between the opening of the first pixel and the opening of the second pixel.

15. The display device of claim 14, further comprising:
a fluid passage that is formed between the opening of the first pixel and the opening of the second pixel and in which the middle bank part is not disposed.

16. The display device of claim 1, further comprising:
a color filter layer disposed on the light controlling layer and including a color filter, wherein
the display layer includes a light emitting element that provides light to a light emitting area, and
the light emitting area overlaps the color filter and the color conversion layer in a plan view.

17. The display device of claim 16, further comprising:
a sub-pixel area in which light of a color is provided; and
a non-sub-pixel area adjacent to the sub-pixel area, wherein
the sub-pixel area includes:
a first sub-pixel area in which light of a first color is provided,
a second sub-pixel area in which light of a second color is provided, and
a third sub-pixel area in which light of a third color is provided, and the light emitting element emits light including a light component of the third color.

18. A method of manufacturing a display device, the method comprising:
manufacturing a display layer; and
forming a light controlling layer on the display layer, wherein
the forming of the light controlling layer includes:
patterning a bank and a middle bank part on the display layer; and
patterning a color conversion layer and a scattering layer on the display layer, and
the patterning of the bank and the middle bank part includes forming an opening in which the bank and the middle bank part are not disposed, and
the color conversion layer includes a base color conversion layer and a protruding color conversion layer, and
the patterning of the color conversion layer includes disposing the base color conversion layer in the opening and disposing the protruding color conversion layer to overlap the middle bank part in a plan view.

19. The method of manufacturing the display device of claim 18, wherein
the patterning of the bank and the middle bank part includes forming an inkjet margin area that overlaps the middle bank part in a plan view, and
the patterning of the color conversion layer includes providing ink to an ink provision area formed across the opening and the inkjet margin area.

20. The method of manufacturing the display device of claim 19, wherein the patterning of the color conversion layer includes moving the ink provided in the ink provision area to an area within the opening.

21. The method of manufacturing the display device of claim 18, wherein
the protruding color conversion layer includes a plurality of protruding color conversion layers, and
some of the plurality of protruding color conversion layers are disposed on a side of the base color conversion layer, and others of the plurality of protruding color conversion layers are disposed on another side of the base color conversion layer.

22. The method of manufacturing the display device of claim 19, wherein
the opening includes a plurality of openings respectively included in different pixels, and
the inkjet margin area is disposed between the plurality of openings.

23. The method of manufacturing the display device of claim 19, wherein
the ink provision area has an ink area length,
the opening has an opening width, and
the ink area length is larger than the opening width.

24. The method of manufacturing the display device of claim 18, wherein the patterning of the bank and the middle bank part includes forming the bank and the middle bank part using a mask or slit-type mask including a halftone area.
